(19) United States
(12) Patent Application Publication
(10) Pub. No.: US 2025/0290205 A1
(43) Pub. Date: Sep. 18, 2025

(54) PROCESS FOR ETCHING CIRCUIT BOARD WITH ALKALINE TETRAAMMINECOPPER (II) SULFATE AND APPARATUS THEREFOR

(71) Applicants: Tao Ye, Guangzhou (CN); Yiting Ye, Guangzhou (CN)

(72) Inventors: Tao Ye, Guangzhou (CN); Yiting Ye, Guangzhou (CN)

(21) Appl. No.: 19/223,101

(22) Filed: May 30, 2025

Related U.S. Application Data
(63) Continuation of application No. PCT/CN2023/120127, filed on Sep. 20, 2023.

(30) Foreign Application Priority Data
Nov. 30, 2022 (CN) 202211514488.0
Dec. 2, 2022 (CN) 202211536732.3
Mar. 17, 2023 (CN) 202310262402.8
Jun. 15, 2023 (CN) 202310711283.X

(51) Int. Cl. C23F 1/34; H05K 3/00

(52) U.S. Cl. CPC C23F 1/34; H05K 3/002; H05K 3/0085; H05K 2203/0793; H05K 2203/125

(57) ABSTRACT

The present disclosure discloses a process for etching a circuit board with alkaline tetraamminecopper (II) sulfate, including an etching solution for etching the circuit board coated with an etching-resist metal layer, where the etching solution includes tetraamminecopper (II) sulfate, a complexed ammonia supply source, and a formate supply source; and the tetraamminecopper (II) sulfate serves as a copper etching agent to etch the circuit board, and the copper etching agent in the etching solution is regenerated by a copper etching agent-oxidation regeneration reaction supply source to maintain an etching rate. The present disclosure solves the production process problem that an etching solution causes corrosion to an etching-resist silver or tin layer in the prior art.

### CROSS-REFERENCE TO RELATED APPLICATIONS

The present application is a continuation application of PCT application No. PCT/CN2023/120127 filed on Sep. 20, 2023, which claims the benefit of Chinese Patent Application No. 202211514488.0 filed on Nov. 30, 2022, Chinese Patent Application No. 202211536732.3 filed on Dec. 2, 2022, Chinese Patent Application No. 202310262402.8 filed on Mar. 17, 2023, and Chinese Patent Application No. 202310711283.X filed on Jun. 15, 2023. The contents of all of the aforementioned applications are incorporated by reference herein in their entirety.

### TECHNICAL FIELD

The present disclosure belongs to the field of circuit board etching production processes, and specifically relates to a process for etching a circuit board with alkaline tetraamminecopper (II) sulfate and an apparatus therefor.

### BACKGROUND

Currently, common circuit board etching solutions include acidic cupric chloride etching solutions and alkaline ammonium cupric chloride etching solutions. Main components in each alkaline ammonium cupric chloride etching solution are ammonia water, ammonium chloride, and an ammonium cupric chloride complex, and some alkaline ammonium cupric chloride etching solution formulas further include an additive such as ammonium carbonate. In an alkaline ammonium cupric chloride etching solution, an ammonium cupric chloride complex [Cu(NH₃)₄]Cl₂ serves as a copper etching agent. During an etching process, [Cu(NH₃)₄]Cl₂ is converted into [Cu(NH₃)₂]Cl without an etching ability due to a copper etching reaction, and [Cu(NH₃)₂]Cl can be oxidized into [Cu(NH₃)₄]Cl₂ once again by oxygen in the air to participate in etching.

According to page 403 of a middle volume of “Printed Electronic Circuit Technology (Fifth Edition)”, for alkaline ammonium cupric chloride etching solutions, when a copper ion concentration is 0 g/L to 82 g/L, an etching time is long; when a copper ion concentration is 82 g/L to 120 g/L, an etching rate is low and a solution is difficult to control; and when a copper ion concentration is 135 g/L to 165 g/L, an etching rate is high and a solution is stable.

Industrially, an etching solution to allow an etching operation, namely, an etching solution on an etching production line, is called an etching working solution. During a chemical etching reaction, in order to maintain a stable component ratio of an etching working solution, it is necessary to add an additional solution as an etching sub-solution. A solution overflowing from an etching operation system due to the addition of an etching sub-solution usually becomes a waste etching solution.

In the industry, there are circuit board products with etching-resist metal layers produced through pattern plating, where these circuit board products are plated with gold, silver, tin, or the like to form a pattern of an etching-resist metal layer for etching. The most common process for producing a circuit board plated with an etching-resist metal layer is as follows:
(1) a photosensitive film is pasted or a photosensitive ink is coated on a copper-clad laminate;
(2) a pattern is formed on the copper-clad laminate through exposure and development, and a thickened copper-plated circuit is made according to the pattern;
(3) then the etching-resist metal layer is plated on the thickened copper-plated circuit; and
(4) film removal is conducted to facilitate the subsequent etching for a circuit board product.

When the existing alkaline ammonium cupric chloride etching solution is used subsequently for etching of a circuit board with an etching-resist silver or tin layer produced by the above process, the etching-resist silver or tin layer will be constantly thinned and narrowed due to the corrosion of a large number of chloride ions in the etching solution, such that a copper circuit under the etching-resist metal layer is easily exposed in the etching solution and the copper circuit is etched and broken, resulting in a scrapped product.

Although the above problem can be solved by thickening and widening an etching-resist metal layer to enhance the protection for a copper circuit, this solution increases the production consumables to increase a cost, makes a film removal process difficult to cause incomplete film removal, and may even cause the phenomenon that a photosensitive film/ink cannot be removed because of being sandwiched at a junction of an etching-resist metal layer and a copper surface.

In addition, when the existing alkaline ammonium cupric chloride etching solutions are adopted, a waste liquid needs to be recovered and recycled. Currently, waste etching solutions can be sold to environmental protection companies for treatment, and some manufacturers also use a device to extract copper from a waste etching solution and recycle the waste etching solution in their factories. In the prior art, an extraction-electrolysis method is the most common method for extracting copper from a waste etching solution to allow regeneration in a factory. The whole process of the extraction-electrolysis method is complicated and cumbersome. The extraction-electrolysis method is specifically as follows: an extracting agent is used to extract copper from a waste alkaline ammonium cupric chloride etching solution, then reverse extraction is conducted with sulfuric acid to obtain a cupric sulfate solution, and then electrolysis is conducted to extract copper. A copper ion in the waste alkaline ammonium cupric chloride etching solution generates a chelate with the extracting agent and enters an organic phase, and hydrogen in the extracting agent is released into the waste alkaline ammonium cupric chloride etching solution to reduce a pH of the waste alkaline ammonium cupric chloride etching solution. Therefore, when a raffinate produced in the extraction-electrolysis method is used to prepare a regenerated etching sub-solution, a large amount of ammonia needs to be supplemented, and only the use of highly-toxic liquid ammonia can avoid the volume expansion of a regenerated etching sub-solution. Liquid ammonia is highly susceptible to vaporization, and may cause severe frostbite when exposed to the skin. A person can be poisoned after staying in the air with an ammonia concentration of 0.5% to 0.6% (in volume) for 0.5 h, and a fatal accident may occur in the air with an ammonia concentration of more than 0.6% to 1%. In addition, because the raffinate includes an organic extracting agent with a corrosion-inhibiting effect, a regenerated etching sub-solution prepared from the raffinate will affect a quality and efficiency of etching production when used in the etching production. Therefore, in recent years, a direct electrolysis method has been used to extract copper from a waste alkaline ammonium cupric chloride etching solution to allow regeneration. However, because a waste alkaline ammonium cupric chloride etching solution includes both chloride ions and ammonia, ammonia in the waste alkaline ammonium cupric chloride etching solution will be consumed due to a chemical reaction of the ammonia with a chlorine gas produced during direct electrolysis to recover copper, resulting in the consumption and waste of the raw material. In addition, the use of a residual solution after cooper extraction by electrolysis to prepare a regenerated etching sub-solution requires highly-toxic liquid ammonia, which makes it difficult to promote the direct electrolysis method.

An acidic cupric chloride etching solution is acidic, and thus can cause intense corrosion to etching-resist metal layers other than etching-resist gold layers. Therefore, in the industry, alkaline ammonium cupric chloride etching solutions are still used for etching production of circuit boards with widened and thickened etching-resist silver or tin layers.

In the prior art, some researchers have tried to use tetraamminecopper (II) sulfate [Cu(NH₃)₄]SO₄ as a copper etching agent because tetraamminecopper (II) sulfate [Cu(NH₃)₄]SO₄ can also react with copper and does not include chloride ions with high corrosion to metals. However, because [Cu₂(NH₃)₄]SO₄ produced from [Cu(NH₃)₄]SO₄ after participating an etching reaction reacts with oxygen in the air slowly to produce [Cu(NH₃)₄]SO₄, an etching rate of a [Cu(NH₃)₄]SO₄ solution is very low and cannot meet the requirement of large-scale production when there are no other additives or auxiliary means. Therefore, [Cu(NH₃)₄]SO₄ has not been used in practice.

The Chinese patent CN85106153A discloses a process for etching a copper film on a printed circuit board (PCB), which can solve the problem that a [Cu(NH₃)₄]SO₄ solution exhibits a low etching rate and the problem that copper extracted from an etching solution through electrolysis has no adhesion, is easy to fall off, and can hardly be removed from an electrode because vanadium or a vanadium compound is added as a catalyst to the etching solution to promote a copper etching reaction in the prior art. In this etching process, an etching solution including [Cu(NH₃)₄]SO₄, NH₃, (NH₄)₂SO₄, and a bromine-containing catalyst is used for etching. The bromine-containing catalyst allows the formation of an adhesive and flexible copper layer that can be easily peeled off on a cathode after electrolysis of the etching solution, and can also increase an etching rate. In this etching process, the copper etching agent [Cu(NH₃)₄]SO₄ is regenerated through oxidation with oxygen in the air, and an electrolytic cell is adopted to appropriately remove copper ions in the etching solution that increase with an etching time. Specifically, the etching solution is added to an undivided electrolytic cell, and [Cu(NH₃)₄]SO₄ is electrochemically reduced into metallic copper on a cathode to reduce a copper ion concentration in the etching solution, which does not involve the process condition of electrolytic anodization to regenerate the copper etching agent. A solution produced after electrolysis to allow copper extraction is different from an etching working solution merely in a concentration of each component, where the solution produced after electrolysis to allow copper extraction has a lower copper ion concentration and higher NH₃ and (NH₄)₂SO₄ concentrations than the etching working solution and thus can be reused as a regenerated etching sub-solution in an etching operation. However, due to similar properties of a bromine compound to a chlorine compound, the etching process disclosed in this patent still faces the problem of corrosion to an etching-resist silver or tin layer, and has not been used in actual etching production.

In summary, a novel etching solution that is friendly to etching-resist silver or tin layers is required in the industry, such that the deposition of only a very thin etching-resist silver or tin layer on a pattern circuit of a copper-clad laminate can meet the requirements of a circuit board etching process, which can not only reduce the consumption of a precious metal raw material, but also help to solve the problem that the subsequent film removal is difficult due to a very thin etching-resist metal layer. In addition, a waste etching solution is preferably 100% recycled to reduce an etching production cost and environmental pollution.

### SUMMARY

The present disclosure improves an etching production process in view of the problem that an etching solution causes corrosion to an etching-resist silver or tin layer in the prior art, and manufactures an apparatus suitable for the etching process of the present disclosure.

A first objective of the present disclosure is to provide a process for etching a circuit board with alkaline tetraamminecopper (II) sulfate.

A second objective of the present disclosure is to provide an apparatus suitable for the process for etching a circuit board with alkaline tetraamminecopper (II) sulfate.

The first objective of the present disclosure is allowed by the following technical solutions:

A process for etching a circuit board with alkaline tetraamminecopper (II) sulfate is provided, including an etching solution for etching the circuit board coated with an etching-resist metal layer, where the etching solution includes tetraamminecopper (II) sulfate, a complexed ammonia supply source, and a formate supply source; and the tetraamminecopper (II) sulfate serves as a copper etching agent to etch the circuit board, and the copper etching agent in the etching solution is regenerated by a copper etching agent-oxidation regeneration reaction supply source to maintain an etching rate.

The inventors have confirmed through long-term practical experience and experiments that concentrations of various ions in the etching solution need to cooperate with each other to allow excellent etching performance. Specifically, in the etching solution, a concentration of copper ions is 10 g/L to 140 g/L, a pH is 7 to 11.5, a molar concentration of sulfate ions is at least 0.01 time a molar concentration of copper ions and does not exceed 4 mol/L, a total molar concentration of ammonia and ammonium ions is at least 1 time the molar concentration of copper ions and does not exceed 18 mol/L, and a concentration of formate ions is 0.0001 mol/L to 8 mol/L, where the total molar concentration of ammonia and ammonium ions refers to a total molar concentration of free ammonia, ammonium ions, and ammonia and ammonium ions in a copper-ammonia complex in the etching solution.

Preferably, in the etching solution, a pH is 7.6 to 11, a concentration of copper ions is 40 g/L to 130 g/L, a molar concentration of sulfate ions is at least 0.05 time a molar concentration of copper ions and does not exceed 3.8 mol/L, and a total molar concentration of ammonia and ammonium ions is at least 1 time the molar concentration of copper ions and does not exceed 17 mol/L. When the concentration of copper ions in the etching solution is higher than 130 g/L and the etching solution stands for a specified period of time, a copper salt is easily crystallized and precipitated to block a nozzle and a liquid flow pipeline.

More preferably, in the etching solution, a concentration of copper ions is 45 g/L to 120 g/L, a pH is 8.0 to 10.0, a molar concentration of sulfate ions is at least 0.3 time a molar concentration of copper ions and does not exceed 3.5 mol/L, and a total molar concentration of ammonia and ammonium ions is at least 2.0 times the molar concentration of copper ions and does not exceed 16 mol/L.

Preferably, the molar concentration of copper ions is not higher than a sum of the molar concentration of sulfate ions and a half of the molar concentration of formate ions in the etching solution.

The complexed ammonia supply source of the present disclosure is a chemical capable of providing ammonia and/or ammonium ions to participate in a chemical regeneration reaction of tetraamminecopper (II) sulfate as a copper etching agent and produce complexed ammonia; and the complexed ammonia supply source includes, but is not limited to, one or more selected from the group consisting of ammonia water, ammonia, ammonium carbonate, ammonium bicarbonate, ammonium sulfate, ammonium bisulfate, and ammonium formate.

The formate supply source of the present disclosure is formic acid and/or ammonium formate; and the formate supply source is provided to increase an upper limit of copper dissolution in the etching solution, such that control parameters for a copper ion concentration in an etching working solution can be improved to promote a chemical reaction for etching copper. When the formate supply source is ammonium formate, ammonium formate serves as both a complexed ammonia supply source and a formate supply source.

The formate supply source adopted in the present disclosure plays the following roles:
1. The formate supply source can stabilize copper ions or copper-ammonia complex ions in the etching solution: Because a solubility of cupric sulfate is much lower than a solubility of cupric chloride and is significantly affected by a temperature, tetraamminecopper (II) sulfate is easy to become cupric sulfate and thus is crystallized and precipitated when at a high concentration in an alkaline tetraamminecopper (II) sulfate etching solution. Therefore, the alkaline tetraamminecopper (II) sulfate etching solution of the present disclosure includes formic acid and/or ammonium formate that can provide formate anions for stabilizing the copper ions or copper-ammonia complex ions in the etching solution. On the one hand, increased copper ions can exist in the etching solution without being crystallized and precipitated to increase a copper etching agent concentration in the etching solution, thereby improving an etching rate. On the other hand, a change of a solubility of copper ions in the etching solution caused by a temperature can be reduced, and it is not prone to cupric sulfate crystallization and precipitation when a temperature of an etching working solution drops during shutdown and maintenance, which can improve the situation that a pipeline and a nozzle are blocked due to crystallization. In addition, since most of components in the etching solution are ionized as cations and anions, when a sulfate concentration in the etching solution is low, formate ions can make increased copper-ammonia complex ions stably present in the etching solution, thereby increasing a copper etching agent concentration in the etching solution.
2. A formate can also play a role of temporarily storing ammonia in the alkaline tetraamminecopper (II) sulfate etching solution: When an ammonia concentration is low, a formate temporarily storing ammonia will release NH₄⁺ timely to supplement the etching raw material, which can improve an oxidation regeneration rate of the copper etching agent and guarantee an etching rate under a same pH of an etching working solution, as shown in the following chemical equation:

HCOONH₄+H₂O⇄HCOOH+NH₄OH.

The copper etching agent-oxidation regeneration reaction supply source of the present disclosure is an oxidation electrolytic cell configured to allow an oxidation regeneration reaction for an etching working solution. The oxidation electrolytic cell is provided with an electrolytic cell separator configured to divide the oxidation electrolytic cell into an anode cell zone and a cathode cell zone; and the anode cell zone is connected through a pipeline to an etching solution tank (namely, an etching machine) that is filled with an etching working solution and is conducting etching, such that the etching working solution is able to circulate between the anode cell zone and the etching solution tank to maintain a concentration of a copper etching agent in the etching working solution. The electrolytic cell separator of the oxidation electrolytic cell is configured to effectively prevent cations in the anode cell zone from entering the cathode cell zone, and is specifically one or more selected from the group consisting of an anion exchange membrane, a bipolar membrane, and a reverse osmosis membrane. The objective of the present disclosure can be allowed by adopting an electrolyte aqueous solution as an electrolyte in the cathode cell zone of the oxidation electrolytic cell. The reverse osmosis membrane adopted in the present disclosure refers to a membrane itself rather than a reverse osmosis membrane component or a reverse osmosis device, and the objective of the present disclosure is allowed based on a microporous structure and material characteristics of the reverse osmosis membrane.

A working principle of regenerating the copper etching agent in the etching solution by the copper etching agent-oxidation regeneration reaction supply source in the present disclosure is as follows: Due to the proceed of a chemical copper-etching reaction, the copper etching agent in the etching working solution is reduced into a cuprous ammonia complex, and then the cuprous ammonia complex flows into the anode cell zone of the oxidation electrolytic cell to directly undergo an electrochemical oxidation reaction at an electrolytic anode, such that the cuprous ammonia complex can be quickly and efficiently regenerated into the copper etching agent and then returned to etching production to further participate in etching. The copper etching agent in the etching solution in the anode cell zone of the oxidation electrolytic cell is produced by an electrochemical oxidation reaction, but a copper ion concentration in the etching solution remains unchanged, that is, a stabilized copper ion concentration in the etching working solution in the etching machine is consistent with a copper ion concentration in an anode electrolyte of the oxidation electrolytic cell.

A chemical reaction principle of the alkaline tetraamminecopper (II) sulfate etching solution of the present disclosure during a copper-etching production process is as follows:

an etching reaction: Cu(NH₃)₄SO₄+Cu→Cu₂(NH₃)₄SO₄; and
an oxidation regeneration reaction of the copper etching agent in the anode cell zone of the oxidation electrolytic cell:

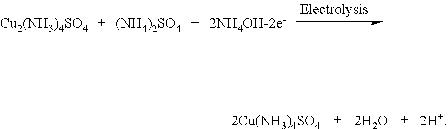

When the electrolytic cell separator of the oxidation electrolytic cell is a bipolar membrane, water molecules will be electrolyzed in the bipolar membrane during an electrolysis process to continuously generate hydroxide ions, and the hydroxide ions enter the anode cell zone of the oxidation electrolytic cell. When the electrolytic cell separator of the oxidation electrolytic cell is a reverse osmosis membrane, a water electrolysis reaction occurs on an electrolysis electrode during an electrolysis process to generate hydroxide ions and hydrogen ions, and the hydroxide ions and hydrogen ions can pass through the reverse osmosis membrane from one side of the reverse osmosis membrane and enter a cell zone at the other side of the reverse osmosis membrane to further promote the water electrolysis reaction. Therefore, when the above two membranes are adopted, the following side reaction will occur: 4OH⁻+4e⁻→2H₂O+O₂↑.

The copper etching agent-oxidation regeneration reaction supply source in the present disclosure plays a key role in the exertion of excellent etching performance of the alkaline tetraamminecopper (II) sulfate etching solution during a practical application. In view of the shortcoming that an oxidation reaction of [Cu₂(NH₃)₄]SO₄ with oxygen is slow, the alkaline tetraamminecopper (II) sulfate etching solution of the present disclosure is improved by directly regenerating a copper etching agent in the alkaline tetraamminecopper (II) sulfate etching solution through an electrochemical oxidation reaction at an electrolytic anode of the oxidation electrolytic cell, which can solve the regeneration problem of the copper etching agent. This measure of the present disclosure solves the following process pain points brought by tetraamminecopper (II) sulfate itself:
1. A regeneration reaction rate for the copper etching agent of tetraamminecopper (II) sulfate under oxidation regeneration conditions for conventional copper etching agents is low: Because a volume of a sulfate ion is much higher than a volume of a chloride ion, the sulfate ion significantly affects a reaction rate of molecules, a structure of a complex, a viscosity of a solution, a solubility of a copper salt, or the like, such that a regeneration rate of the copper etching agent of tetraamminecopper (II) sulfate is much lower than a regeneration rate of the copper etching agent of a ammonium cupric chloride complex under oxidation regeneration conditions for conventional copper etching agents, which makes an etching rate low and fail to meet the requirement of efficient etching production.
2. A low solubility of cupric sulfate leads to a low copper ion concentration in the etching solution of the present disclosure: A copper ion concentration in the alkaline tetraamminecopper (II) sulfate etching solution of the present disclosure is lower than a copper ion concentration in the existing alkaline ammonium cupric chloride etching solution. Thus, if it cannot be guaranteed that most of copper ions in the alkaline tetraamminecopper (II) sulfate etching solution exist in a form of a copper etching agent, the etching solution can hardly meet the requirement of etching production of a thick copper circuit board due to an insufficient copper etching agent concentration.

During a continuous production process, in order to maintain a stable component ratio of an etching working solution, it is necessary to supplement an etching sub-solution to the etching working solution. The alkaline tetraamminecopper (II) sulfate etching sub-solution adopted in the present disclosure includes a sulfate and the complexed ammonia supply source as a main component, and thus the etching sub-solution can supplement the complexed ammonia supply source and sulfate ions for the etching working solution. Specifically, one etching sub-solution or a combination of two or more etching sub-solutions is added.

Since the etching working solution circulates between the etching machine and the anode cell zone of the oxidation electrolytic cell, the etching sub-solution can be added to any one or more selected from the group consisting of the following: the etching working solution in the etching machine, an anode electrolyte in the oxidation electrolytic cell, and a mixed solution of the etching working solution and the anode electrolyte.

As a preferred embodiment of the present disclosure, a main component of the alkaline tetraamminecopper (II) sulfate etching sub-solution is a combination of a complexed ammonia supply source A, a complexed ammonia supply source B, and a formate supply source, where the complexed ammonia supply source A is ammonium sulfate and/or ammonium bisulfate, and the complexed ammonia supply source B is one or more selected from the group consisting of ammonia water, an ammonia gas, liquid ammonia, ammonium carbonate, ammonium bicarbonate, and ammonium formate. Preferably, main components of the alkaline tetraamminecopper (II) sulfate etching sub-solution are ammonium sulfate, ammonia water, and a formate supply source.

The following improvement can be conducted in the present disclosure: During an etching process, ammonia and/or water are/is added to the etching working solution and/or the anode electrolyte in the oxidation electrolytic cell, where ammonia and ammonia water can supplement ammonia in the etching working solution to promote a chemical regeneration reaction for the copper etching agent, and ammonia water and water can provide water to improve the fluidity of the etching working solution. Since the etching working solution circulates between the etching machine and the anode cell zone of the oxidation electrolytic cell during an etching process, although the etching sub-solution is added to the etching working solution during the etching process, the etching working solution is still prone to ammonia volatilization and water loss due to electrolytic heating, a heat release of an etching reaction, and an electrolysis reaction of water, which reduces the fluidity of a solution and affects the etching performance.

As a preferred embodiment of the present disclosure, during etching production, at least one selected from the group consisting of a pH meter, a gravitometer, a photoelectric colorimeter, an oxidation-reduction potential (ORP) meter, a liquid level meter, and a thermometer is used to detect parameters of the etching working solution and/or the anode electrolyte in the oxidation electrolytic cell. An ORP value of a solution during a regeneration oxidation reaction can be detected to monitor a regeneration situation of the copper etching agent.

Preferably, a supplementation operation of an etching sub-solution and/or ammonia water to the etching working solution and/or the anode electrolyte in the oxidation electrolytic cell is controlled according to detection results of the pH meter and/or the gravitometer, and a working current, a start, or a shutdown of an electrolytic power supply is controlled according to detection results of the ORP meter, such that a copper etching agent concentration in the etching working solution is stable and components in the etching working solution are balanced and stabilized to allow efficient continuous etching production.

More preferably, when a circuit board coated with an etching-resist silver layer is etched, an ORP value of the etching working solution during a regeneration oxidation reaction is detected to control the ORP of the etching working solution at no more than 350 mV, thereby reducing the phenomenon that the etching-resist silver layer is oxidized and dissolved.

The alkaline tetraamminecopper (II) sulfate etching process of the present disclosure is suitable for etching of various circuit boards with etching-resist metal layers, including, but not limited to, circuit boards with etching-resist gold, silver, tin, or alloy layers.

The inventors have found through many tests and comparisons that a main reason for the alkaline ammonium cupric chloride etching solution in the prior art to attack an etching-resist silver or tin layer is the presence of a large number of chloride ions in the etching solution to react with a surface of silver or tin to produce silver chloride or stannous chloride. The silver chloride can be dissolved in ammonia water, such that silver is further exposed and corroded by the etching solution. The alkaline tetraamminecopper (II) sulfate etching solution of the present disclosure can avoid the above situation, significantly reduce the attack on etching-resist silver or tin layers, and solve the environmental protection problem that there are chloride ions in the etching solution in the prior art, that is, a circuit board product of the alkaline tetraamminecopper (II) sulfate etching solution can easily meet the new eco-friendly product requirement that a circuit board product should have a low chlorine-containing compound content. It should be noted that the use of tap water or a material including a small quantity of chloride ion impurities to prepare the alkaline tetraamminecopper (II) sulfate etching solution of the present disclosure conforms to the technical quality requirements of the product of the present disclosure.

It has been repeatedly verified by the inventors that the use of the alkaline tetraamminecopper (II) sulfate etching process of the present disclosure can facilitate the removal of a film residue left on a circuit board in a film removal procedure before etching to reduce the phenomenon of poor etching caused by incomplete film removal, thereby improving an etching quality. This is because the alkaline tetraamminecopper (II) sulfate etching solution of the present disclosure includes a large number of sulfate ions, has a high pH, and is easy to chemically react with a photosensitive film and a photosensitive ink to make a film residue fall off. Therefore, the consumption of an organic film removal solution can be reduced in the film removal procedure, which can reduce both the film removal cost and the organic waste liquid pollution.

In the present disclosure, an etching working temperature is 10° C. to 60° C. When a circuit board with an etching-resist gold or tin layer is etched, the etching working temperature is preferably 40° C. to 60° C. because an etching rate of the alkaline tetraamminecopper (II) sulfate etching solution of the present disclosure increases with the increase of a temperature. When a circuit board with an etching-resist silver layer is etched, the etching working temperature is preferably 10° C. to 40° C. because a high etching temperature will accelerate an oxidation reaction between silver and oxygen dissolved in the etching solution to make the silver dissolved in the etching solution. When a low etching temperature is adopted and an oxygen content in the etching solution is reduced, an etching-resist silver layer can be further protected.

As a preferred embodiment of the present disclosure, before an etching working solution undergoing electrolytic oxidation in the anode cell zone of the oxidation electrolytic cell is returned to etching production, the etching working temperature is adjusted according to a temperature of the etching working solution for etching production. In order to maintain a copper etching agent concentration in the etching working solution, a high circulation flow rate is required between the etching machine and the anode cell zone of the oxidation electrolytic cell. A temperature and a flow rate of an etching working solution returned to etching production after electrolytic oxidation can be controlled to well allow the efficient performance of the etching working solution.

Preferably, when an etching working solution undergoing electrolytic oxidation in the anode cell zone of the oxidation electrolytic cell is returned to the etching machine, a temperature difference between the returned etching working solution and the etching working solution in the etching machine does not exceed 5° C.

The following improvement can be conducted in the present disclosure: The alkaline tetraamminecopper (II) sulfate etching solution of the present disclosure further includes hydroxylamine at a concentration of no more than 5 mol/L to promote a regeneration reaction of the etching solution.

Because hydroxylamine sulfate can undergo a neutralization reaction with the alkaline complexed ammonia supply source in the etching solution to produce hydroxylamine in the etching solution, hydroxylamine sulfate can also be used as a raw material for the hydroxylamine in the etching solution, with a concentration of no more than 2.5 mol/L.

A principle of a role of the hydroxylamine in the alkaline tetraamminecopper (II) sulfate etching process of the present disclosure is as follows:

The hydroxylamine can be gradually decomposed into ammonia (as shown in the following chemical equation) to increase an ammonia concentration in the etching solution and promote a regeneration reaction for the alkaline tetraamminecopper (II) sulfate etching solution:

3NH₂OH→NH₃+N₂+3H₂O.
(1) Copper ions in the alkaline tetraamminecopper (II) sulfate etching solution can catalyze a reaction of hydroxylamine with oxygen to produce hydroxyl radicals, and the hydroxyl radicals are more active than oxygen in terms of chemical properties and thus allow a higher oxidation regeneration rate for the copper etching agent than oxygen:

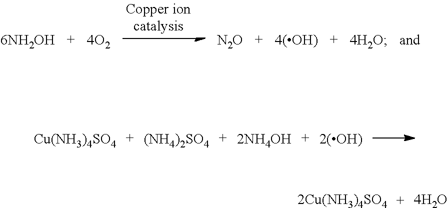

(2) The hydroxylamine is reducible, and can effectively consume oxygen in the etching solution with a low oxygen content to reduce silver oxide generated from oxidation of an etching-resist silver layer by oxygen when a circuit board coated with the etching-resist silver layer is etched, which is conducive to effective protection of the etching-resist silver layer.

Preferably, because the hydroxylamine is unstable and easy to decompose under alkaline conditions, an etching sub-solution including hydroxylamine and/or hydroxylamine sulfate is used immediately after preparation, or a hydroxylamine and/or hydroxylamine sulfate solution with a pH suitable for the etching working solution is prepared and then directly added to the etching working solution according to process requirements, such that hydroxylamine and/or hydroxylamine sulfate can play an optimal chemical role during an etching process.

The following improvement can be conducted in the present disclosure: The copper etching agent-oxidation regeneration reaction supply source further includes oxygen. Specifically, the oxygen is introduced into the etching working solution and/or the anode electrolyte in the oxidation electrolytic cell to assist in a chemical oxidation reaction to regenerate a cuprous ammonia complex in the etching working solution into the copper etching agent. Oxygen sources include, but is not limited to: (1) commercial oxygen, (2) oxygen prepared by a molecular sieve oxygen-production machine, (3) oxygen prepared by a chemical reaction of an oxidant, and (4) oxygen prepared by an electrolysis method. The oxygen sources (1) and (4) have a high oxygen production efficiency and a low cost, and can well meet the needs of industrial large-scale production. The oxygen source (4) can be oxygen escaping during an operation process of the oxidation electrolytic cell and/or oxygen produced by an additional oxygen-production electrolytic cell. The objective of the present disclosure can be allowed as long as oxygen can be generated during an electrolysis operation of an anode of the oxygen-production electrolytic cell. An electrolyte in contact with the electrolytic anode of the oxygen-production electrolytic cell is an electrolyte aqueous solution with a low chloride ion content, and there is no restriction on an electrolyte in contact with an electrolytic cathode of the oxygen-production electrolytic cell.

A chemical oxidation regeneration reaction of oxygen for the copper etching agent is as follows:

2Cu₂(NH₃)₄SO₄+2(NH₄)₂SO₄+4NH₄OH+O₂→4Cu(NH₃)₄SO₄+6H₂O.

Although an oxidation reaction of [Cu₂(NH₃)₄]SO₄ with oxygen is slow, under the premise of regenerating a copper etching agent through electrochemical oxidation to ensure a copper etching agent concentration in the etching working solution, the increase of an oxygen concentration in the etching solution can promote a chemical regeneration reaction for the copper etching agent of tetraamminecopper (II) sulfate and effectively reduce a loss of the complexed ammonia supply source in the etching solution. In addition, when the etching working solution is rich in oxygen, the oxygen will directly oxidize copper into cupric oxide, which is conducive to the conversion of soluble copper-ammonia complex ions in the etching solution, thereby improving an etching rate. However, for a circuit board coated with an etching-resist silver layer, rich oxygen in the etching working solution will oxidize the etching-resist silver layer to produce silver oxide, and the silver oxide is dissolved in the etching solution, which makes the circuit board have a risk of being etched and damaged. Therefore, it is not recommended to use oxygen as a copper etching agent-oxidation regeneration reaction supply source for a circuit board coated with an etching-resist silver layer.

The oxygen-production electrolytic cell can adopt the waste alkaline tetraamminecopper (II) sulfate etching solution of the present disclosure as an electrolyte, and is mainly different from the oxidation electrolytic cell in that: an etching working solution does not circulate between the etching machine and the anode cell zone of the oxygen-production electrolytic cell to allow on-line oxidation of the copper etching agent. After a cuprous ammonia complex in an electrolyte of the oxygen-production electrolytic cell is mostly oxidized, oxygen is mainly produced through electrolysis at the anode during an electrolytic oxygen-production process: 4OH⁻+4e⁻→2H₂O+O₂↑.

The oxygen-production electrolytic cell can also be divided by an electrolytic cell separator into an anode cell zone and a cathode cell zone, and the electrolytic cell separator is one or more selected from the group consisting of a cation exchange membrane, an anion exchange membrane, a bipolar membrane, a reverse osmosis membrane, a neutral filter membrane, and a filter cloth.

The following improvement can be conducted in the present disclosure: A mixing-exchange tank is provided between the etching machine and the anode cell zone of the oxidation electrolytic cell, such that the etching working solution in the etching machine and an anode electrolyte in the oxidation electrolytic cell are mixed and exchanged in the mixing-exchange tank through respective liquid flow circulations. Process parameters of a mixed solution in the mixing-exchange tank are detected through sampling to control an output size of a working current, a start, or a shutdown of an electrolytic power supply of the oxidation electrolytic cell, and/or a flow rate of an etching working solution flowing in or out of the mixing-exchange tank and/or an anode electrolyte in the oxidation electrolytic cell, and/or the addition of at least one selected from the group consisting of ammonia water, ammonia, water, and an etching sub-solution to the mixed solution in the mixing-exchange tank, such that a solution is generated through an oxidation regeneration reaction according to a process and can maintain a required concentration of tetraamminecopper (II) sulfate. The parameters of the mixed solution in the mixing-exchange tank include, but are not limited to, one or more selected from the group consisting of ORP, pH, a specific gravity, a temperature, and a liquid level.

Preferably, an ORP value of the mixed solution in the mixing-exchange tank is higher than an ORP value of the etching working solution, that is, the mixed solution has a higher copper etching agent concentration than the etching working solution. When it is detected that an ORP value of the etching working solution in the etching machine is lower than a process set value, a flow rate of the mixed solution in the mixing-exchange tank that flows into the etching machine is adjusted, such that the copper etching agent in the etching working solution can be supplemented timely. In this way, the efficiency and safety of a control response in an etching and oxidation regeneration system can be improved through pre-preparation of a solution with a high copper etching agent concentration.

The following improvement can be conducted in the present disclosure: A waste alkaline tetraamminecopper (II) sulfate etching solution is subjected to copper and/or silver extraction through electroextraction with a metal electroextraction cell. An electrochemical reaction in which a copper ion is reduced into metallic copper and/or an electrochemical reaction in which a silver ion is reduced into metallic silver occur(s) at an electrolytic cathode of the metal electroextraction cell. When the metal electroextraction cell is not provided with an electroextraction cell separator, an electrolyte includes a waste etching solution and/or a waste etching solution undergoing electrolysis. When the metal electroextraction cell is provided with an electroextraction cell separator configured to divide the metal electroextraction cell into an anode cell zone and a cathode cell zone, a cathode electrolyte includes a waste etching solution and/or a waste etching solution undergoing electrolysis, an anode electrolyte is one or a mixed solution of two or more selected from the group consisting of an etching working solution, a waste etching solution, a cathode electrolyte undergoing electrolysis from the metal electroextraction cell, and a cathode electrolyte undergoing electrolysis from another metal electroextraction cell, and the electroextraction cell separator is one or more selected from the group consisting of a cation exchange membrane, an anion exchange membrane, a bipolar membrane, a reverse osmosis membrane, a neutral filter membrane, and a filter cloth. Therefore, an oxidation electrolytic cell and/or an oxygen-production electrolytic cell can be adopted as the metal electroextraction cell.

When the oxidation electrolytic cell is adopted as the metal electroextraction cell, a main electrochemical reaction occurring in the cathode cell zone is as follows:
(1) When the electroextraction cell separator is an anion exchange membrane:

Cu(NH₃)₄SO₄+4H₂O+2e⁻→2NH₄OH+(NH₄)₂SO₄+Cu+2OH⁻.
(2) When the electroextraction cell separator is a bipolar membrane and/or a reverse osmosis membrane:

Cu(NH₃)₄SO₄+2H₂O+2H⁺+2e⁻→(NH₄)₂SO₄+2NH₄OH+Cu.

After the copper extraction through the electroextraction with the metal electroextraction cell, the waste alkaline tetraamminecopper (II) sulfate etching solution can directly become a regenerated etching sub-solution or can be used as one of raw materials to prepare a regenerated etching sub-solution. The regenerated etching sub-solution plays the same role as the etching sub-solution in the process. Thus, the regenerated etching sub-solution can be used as a part or all of the etching sub-solution, and residual copper ions in the regenerated etching sub-solution do not affect a use effect. When copper is extracted through electroextraction, tetraamminecopper (II) sulfate is reduced into metallic copper, which is accompanied by the generation of ammonia and ammonium sulfate. As a result, a resulting solution has increased ammonia and ammonium sulfate concentrations, and may also include other complexed ammonia supply sources, additives, and copper-ammonia complexes not participating in an electrochemical reaction that are originally present in a waste etching solution.

The following improvement can be further conducted in the present disclosure: When two or more metal electroextraction cells each with an electroextraction cell separator are adopted, such as a grade-A metal electroextraction cell, a grade-B metal electroextraction cell, or the like, progressive electrolysis is conducted to extract copper to reduce the back etching of an electrolyte for metallic copper precipitated on a cathode during a copper electroextraction process, thereby improving a copper collection efficiency. Specifically, a cathode electrolyte of the grade-A metal electroextraction cell includes a waste etching solution, and starting from the grade-B metal electroextraction cell, a cathode electrolyte of a metal electroextraction cell of each grade includes an electrolyzed cathode electrolyte from a metal electroextraction cell of the previous grade.

When a circuit board coated with an etching-resist silver layer is etched for a long time, a small part of the etching-resist silver layer may be oxidized by oxygen and then dissolved in the etching working solution, and the metal electroextraction cell can be adopted to effectively remove silver ions in the etching working solution and/or the waste etching solution. Since silver is preferentially electrochemically reduced compared with copper, graded metal electroextraction cells can be adopted for progressive electrolysis to extract copper, such that silver and copper can be extracted separately through electroextraction. That is, a first metal electroextraction cell is used to remove silver ions in the waste etching solution through electroextraction, and then a second metal electroextraction cell is used to extract copper through electroextraction.

The following improvement can be conducted in the present disclosure: A solution (including an anode electrolyte and/or a cathode electrolyte) produced after copper electroextraction with the metal electroextraction cell is oxidized with oxygen and/or regenerated through an electrochemical oxidation reaction with an electrolytic cell, and then directly used as a regenerated etching sub-solution for an etching procedure or as a raw material to prepare a regenerated etching sub-solution for an etching procedure. This is because the waste alkaline tetraamminecopper (II) sulfate etching solution usually still includes residual copper ions after copper electroextraction, and a larger part of the copper ions exist in a form of cuprous ammonia complex ions and can be oxidized to increase a copper etching agent concentration in a solution, such that a resulting solution can be subsequently used as a regenerated etching sub-solution for etching to ensure a constant etching rate.

The following improvement can be further conducted in the present disclosure: A procedure of washing a cathode copper plate out from an electrolytic cell with water in the electrolytic cell is added to reduce the environmental pollution caused by an electrolyte carried by the cathode copper plate and an ammonia gas escaping when the cathode copper plate is taken out.

The second objective of the present disclosure is to provide an apparatus suitable for the process for etching a circuit board with alkaline tetraamminecopper (II) sulfate.

The apparatus suitable for the process for etching a circuit board with alkaline tetraamminecopper (II) sulfate includes: an etching machine with an alkaline tetraamminecopper (II) sulfate etching solution as an etching working solution, and a copper etching agent-oxidation regeneration reaction supply device, where the copper etching agent-oxidation regeneration reaction supply device is an oxidation electrolytic cell, and the oxidation electrolytic cell is connected to the etching machine through at least two pipelines, such that the etching working solution is able to circulate between the oxidation electrolytic cell and the etching machine, the etching working solution directly undergoes an electrochemical oxidation reaction with an electrolytic anode when entering the oxidation electrolytic cell, and a cuprous ammonia complex in the etching working solution is regenerated into alkaline tetraamminecopper (II) sulfate Cu(NH₃)₄SO₄ as a copper etching agent.

The etching machine is an etching device for a circuit board in the prior art.

The oxidation electrolytic cell is provided with an electrolytic cell separator configured to divide the oxidation electrolytic cell into an anode cell zone and a cathode cell zone, where the anode cell zone is connected through a pipeline to the etching machine, such that the etching solution is able to circulate between the anode cell zone and the etching machine to maintain a concentration of a copper etching agent in the etching solution. The electrolytic cell separator of the oxidation electrolytic cell is configured to effectively prevent cations in the anode cell zone from entering the cathode cell zone, and is specifically one or more selected from the group consisting of an anion exchange membrane, a bipolar membrane, and a reverse osmosis membrane.

The following improvement can be conducted in the present disclosure: The copper etching agent-oxidation regeneration reaction supply device further includes an oxygen supply unit, and the oxygen supply unit is connected to a unit filled with an etching working solution through a pipeline or communicates with the etching working solution through a pipeline, such that alkaline tetraamminecopper (II) sulfate Cu(NH₃)₄SO₄ as a copper etching agent in the etching working solution is able to be regenerated through an oxygen oxidation reaction during an etching process of the etching working solution. The oxygen supply unit is selected from the group consisting of an oxygen-containing steel cylinder, a molecular sieve oxygen-production machine, an oxidant reaction-based oxygen-production device, an oxygen-production electrolytic cell, and an oxidation electrolytic cell from which oxygen escapes during an operation process.

The following improvement can be conducted in the present disclosure: At least one selected from the group consisting of a pH meter, a gravitometer, a photoelectric colorimeter, an ORP meter, a liquid level meter, a thermometer, and a flow meter is provided in the etching machine and/or the oxidation electrolytic cell to detect process parameters, and execution working components such as pumps, valves, electrolytic power supplies, and heat exchangers each are processed and controlled by an automatic program controller.

The following improvement can be conducted in the present disclosure: A mixing-exchange tank is further provided at a connecting pipeline between the etching machine and the anode cell zone of the oxidation electrolytic cell, such that the etching working solution and an anode electrolyte in the oxidation electrolytic cell are mixed and exchanged in the mixing-exchange tank through respective liquid flow circulation pipelines. Process parameters of a solution in the mixing-exchange tank are controlled, and according to detected parameter values, an output size of a working current, a start, or a shutdown of an electrolytic power supply of the electrolytic cell is controlled, and/or at least one selected from the group consisting of ammonia water, ammonia, water, an etching sub-solution, and a regenerated etching sub-solution is added to the mixing-exchange tank, such that a solution is generated through an oxidation regeneration reaction according to a process and can maintain a required concentration of tetraamminecopper (II) sulfate. The parameters of the solution in the mixing-exchange tank include, but are not limited to, one or more selected from the group consisting of ORP, pH, a specific gravity, a temperature, and a liquid level.

Preferably, a variable-frequency pump and/or a valve with a variable gate valve opening is/are provided on a pipeline flowing from the mixing-exchange tank to the etching machine to control a flow rate of the solution, and an ORP value of the solution in the mixing-exchange tank is set to be higher than an ORP value of the etching working solution, that is, a copper etching agent concentration in the solution in the mixing-exchange tank is higher than a copper etching agent concentration in the etching working solution. When it is detected that an on-site ORP value of the etching working solution is lower than a process set value, a flow rate of the solution in the mixing-exchange tank that flows to the etching machine is controlled by adjusting an opening of a valve and/or a rotational speed of a pump in a solution circulation flow system between the etching machine and the mixing-exchange tank, such that the copper etching agent in the etching working solution can be supplemented timely. The efficiency and safety of a control response in an etching and oxidation regeneration system can be improved through pre-preparation and storage of a solution with a high copper etching agent concentration in the mixing-exchange tank.

The following improvement can be further conducted in the present disclosure: A metal electroextraction cell is further provided to receive a waste alkaline tetraamminecopper (II) sulfate etching solution from the etching machine and extract copper and/or silver from the waste alkaline tetraamminecopper (II) sulfate etching solution through electroextraction. When the metal electroextraction cell is not provided with an electroextraction cell separator, an electrolyte includes a waste etching solution and/or a waste etching solution undergoing electrolysis. When the metal electroextraction cell is provided with an electroextraction cell separator configured to divide the metal electroextraction cell into an anode cell zone and a cathode cell zone, a cathode electrolyte includes a waste etching solution and/or a waste etching solution undergoing electrolysis, an anode electrolyte is one or a mixed solution of two or more selected from the group consisting of an etching working solution, a waste etching solution, a cathode electrolyte undergoing electrolysis from the metal electroextraction cell, and a cathode electrolyte undergoing electrolysis from another metal electroextraction cell, and the electroextraction cell separator is one or more selected from the group consisting of a cation exchange membrane, an anion exchange membrane, a bipolar membrane, a reverse osmosis membrane, a neutral filter membrane, and a filter cloth.

The following improvement can be further conducted in the present disclosure: When two or more metal electroextraction cells each with an electroextraction cell separator are adopted, such as a grade-A metal electroextraction cell, a grade-B metal electroextraction cell, or the like, progressive electrolysis is conducted to extract copper to improve an efficiency of copper electroextraction; a cathode electrolyte of the grade-A metal electroextraction cell includes a waste etching solution; and starting from the grade-B metal electroextraction cell, a cathode electrolyte of a metal electroextraction cell of each grade includes an electrolyzed cathode electrolyte from a metal electroextraction cell of the previous grade. That is, if the cathode electrolyte of the grade-A metal electroextraction cell includes a waste etching solution, and after an electrochemical reaction, a solution overflowing from the grade-A metal electroextraction cell is drained to a cathode cell zone of the grade-B metal electroextraction cell for metal electroextraction, there is a two-stage progressive device structure. If a cathode electrolyte of the grade-B metal electroextraction cell after undergoing copper electroextraction is drained to a cathode cell zone of a grade-C metal electroextraction cell for further metal electroextraction, there is a three-stage progressive device structure for copper electroextraction.

The following improvement can be further conducted in the present disclosure: A heat exchanger is further provided to control each solution in the apparatus according to a process temperature requirement, such that a chemical reaction of the solution is safe and efficient. Specifically, the heat exchanger is arranged in the etching machine and/or the oxidation electrolytic cell and/or the mixing-exchange tank and/or the oxygen-production electrolytic cell and/or the metal electroextraction cell.

The following improvement can be further conducted in the present disclosure: A stirrer is further provided to make a solution in the apparatus have uniform concentration and temperature distributions. Specifically, the stirrer is arranged in the etching machine and/or the oxidation electrolytic cell and/or the mixing-exchange tank and/or the oxygen-production electrolytic cell and/or the metal electroextraction cell.

The following improvement can be further conducted in the present disclosure: A gas-liquid mixer is further provided to drain a gas to promote a reaction of the gas with a solution. The gas-liquid mixer is one or more selected from the group consisting of a vacuum ejector, a spray tower, and a bubbling gas-liquid mixer.

The following improvement can be further conducted in the present disclosure: A tail gas treatment device is further provided to absorb and reuse or eco-friendly treat an ammonia gas and oxygen produced during a chemical etching or regeneration reaction, and the tail gas treatment device communicates with the etching machine and/or the oxidation electrolytic cell and/or the oxygen-production electrolytic cell and/or the metal electroextraction cell. The tail gas treatment device is a combination of a vacuum ejector-type gas-liquid mixer or a spray tower-type gas-liquid mixer with a solution tank, and may have a multi-stage structure.

The following improvement can be further conducted in the present disclosure: A temporary storage tank is further provided to temporarily store a material and/or serve as a chemical reaction tank, and the temporary storage tank is connected to the etching machine and/or the oxidation electrolytic cell and/or the mixing-exchange tank and/or the metal electroextraction cell.

The following improvement can be further conducted in the present disclosure: A solid-liquid separator is further provided, and the solid-liquid separator can be connected to the etching machine, the oxidation electrolytic cell, the mixing-exchange tank, and the temporary storage tank to allow solid-liquid separation for an etching solution, an electrolyte, and a regenerated solution.

The following improvement can be further conducted in the present disclosure: A liquid flow buffer tank is further provided between different reaction tanks to allow a flow of a solution between the tanks.

The following improvement can be further conducted in the present disclosure: A cathode copper plate water-washing unit is further provided in the metal electroextraction cell. When a cathode copper plate needs to be taken out from the metal electroextraction cell after copper electroextraction is completed, in order to reduce the ammonia pollution, the cathode copper plate is first washed with water in the metal electroextraction cell and then taken out for copper recovery.

An anode material of an electrolytic cell in the apparatus of the present disclosure can be selected from the group consisting of gold, platinum, an anode with a titanium-based coating, and conductive graphite. Preferably, the anode material is an anode with a titanium-based coating. A cathode material of the electrolytic cell can be selected from the group consisting of copper, iron, titanium, conductive graphite, and a stainless steel. Preferably, the cathode material is copper or a stainless steel.

Compared with the prior art, the present disclosure has the following beneficial effects:
1. The etching process of the present disclosure improves an etching rate of tetraamminecopper (II) sulfate as a copper etching agent, thereby ensuring a production efficiency.
2. The etching process of the present disclosure causes little corrosion to an etching-resist silver or tin layer, and can be used in the etching production of a circuit board with an etching-resist silver or tin layer on a large scale. The present disclosure solves the production problem that the etching solution in the prior art corrodes an etching-resist silver or tin layer, and reduces the consumption of precious metal raw materials in large quantities for PCB manufacturers, thereby reducing a cost.
3. Because the alkaline tetraamminecopper (II) sulfate etching solution of the present disclosure does not include a large number of chloride ions, when a waste etching solution undergoes electrolysis for copper extraction, there will be no nitrogen trichloride hazard source and no chlorine gas to consume a large amount of ammonia in the waste etching solution. A waste alkaline tetraamminecopper (II) sulfate etching solution after undergoing copper electroextraction can be directly used as a regenerated etching sub-solution, and even if ammonia needs to be supplemented to prepare the regenerated etching sub-solution, it is not necessary to use liquid ammonia.
4. A waste solution produced after the alkaline tetraamminecopper (II) sulfate etching solution of the present disclosure is used for etching includes a small number of chloride ions, and thus the waste solution can be recovered by a simple process and device and is easily 100% recycled, which improves the economic benefits.
5. The alkaline tetraamminecopper (II) sulfate etching solution of the present disclosure includes a small number of chloride ions, and thus can meet the new eco-friendly product requirement that a circuit board product should have a low chlorine-containing compound content during etching.
6. Because the alkaline tetraamminecopper (II) sulfate etching solution of the present disclosure can allow a same etching effect with a thinned etching-resist layer, the difficulty of film removal before etching is greatly reduced, and it is conducive to the removal of a film residue left on a circuit board in the previous film removal procedure to improve an etching quality and reduce the consumption of an organic film removal solution, which can reduce both the production cost and the organic pollution.

### BRIEF DESCRIPTION OF THE DRAWINGS

The present disclosure is further described below with reference to accompanying drawings.

FIG. 1 is a schematic diagram of an apparatus for etching a circuit board with alkaline tetraamminecopper (II) sulfate in Example 1 of the present disclosure;

FIG. 2 is a schematic diagram of an apparatus for etching a circuit board with alkaline tetraamminecopper (II) sulfate in Example 2 of the present disclosure;

FIG. 3 is a schematic diagram of an apparatus for etching a circuit board with alkaline tetraamminecopper (II) sulfate in Example 3 of the present disclosure;

FIG. 4 is a schematic diagram of an apparatus for etching a circuit board with alkaline tetraamminecopper (II) sulfate in Example 4 of the present disclosure;

FIG. 4A is an enlarged view of 4-A in FIG. 4;

FIG. 4B is an enlarged view of 4-B in FIG. 4;

FIG. 5 is a schematic diagram of an apparatus for etching a circuit board with alkaline tetraamminecopper (II) sulfate in Example 5 of the present disclosure;

FIG. 5A is an enlarged view of 5-A in FIG. 5;

FIG. 5B is an enlarged view of 5-B in FIG. 5;

FIG. 6 is a schematic diagram of an apparatus for etching a circuit board with alkaline tetraamminecopper (II) sulfate in Example 6 of the present disclosure;

FIG. 6A is an enlarged view of 6-A in FIG. 6;

FIG. 6B is an enlarged view of 6-B in FIG. 6;

FIG. 7 is a schematic diagram of an apparatus for etching a circuit board with alkaline tetraamminecopper (II) sulfate in Example 7 of the present disclosure;

FIG. 7A is an enlarged view of 7-A in FIG. 7;

FIG. 7B is an enlarged view of 7-B in FIG. 7;

FIG. 7C is an enlarged view of 7-C in FIG. 7;

FIG. 8 is a schematic diagram of an apparatus for etching a circuit board with alkaline tetraamminecopper (II) sulfate in Example 8 of the present disclosure;

FIG. 8A is an enlarged view of 8-A in FIG. 8;

FIG. 8B is an enlarged view of 8-B in FIG. 8;

FIG. 8C is an enlarged view of 8-C in FIG. 8;

FIG. 9 is a schematic diagram of an apparatus for etching a circuit board with alkaline tetraamminecopper (II) sulfate in Example 9 of the present disclosure;

FIG. 9A is an enlarged view of 9-A in FIG. 9;

FIG. 9B is an enlarged view of 9-B in FIG. 9;

FIG. 10 is a schematic diagram of an apparatus for etching a circuit board with alkaline tetraamminecopper (II) sulfate in Examples 10 to 14 of the present disclosure;

FIG. 10A is an enlarged view of 10-A in FIG. 10;

FIG. 10B is an enlarged view of 10-B in FIG. 10;

FIG. 10C is an enlarged view of 10-C in FIG. 10; and

FIG. 11 is a schematic diagram of an etching apparatus in Comparative Example 1.

Reference numerals: 1: etching machine, 2: oxidation electrolytic cell, 3: oxygen-production electrolytic cell, 4: electrolytic anode, 5: electrolytic cathode, 6: electrolytic cell separator, 7: electrolytic power supply, 8: oxygen-containing steel cylinder, 9: liquid ammonia-containing steel cylinder, 10: temporary storage tank, 11: solid feeder, 12: impeller stirrer, 13: liquid flow stirrer, 14: tail gas treatment device, 15: valve, 16: pump, 17: circuit board, 18: tank sealing cover, 19: vacuum ejector, 20: pipeline bubbling gas-liquid mixer, 21: spray-type gas-liquid mixer, 22: liquid flow buffer tank, 23: molecular sieve oxygen-production machine, 24: oxygen-containing steel cylinder, 25: electric heater, 26: heat exchanger, 27: gas-pressurized pump, 28: sensor, 29: automatic program controller, 30: nozzle, 31: liquid ammonia-containing steel cylinder, 32: solution undergoing copper electroextraction, 33: etching solution additive, 34: liquid ammonia, 35: ammonia water, 36: ammonium carbonate, 37: ammonium bicarbonate, 38: ammonia gas, 39: clear water, 40: tetraamminecopper (II) sulfate, 41: formic acid, 42: ammonium formate, 43: ammonium sulfate, 44: hydroxylamine sulfate, 45: hydroxylamine sulfate, 46: hydroxylamine, 47: etching working solution (etching solution), 48: waste etching solution, 49: etching sub-solution, 50: regenerated etching sub-solution, 51: oxidant, 52: oxygen, 53: manganese dioxide, 54: electrolyte solution, 55: electroplating brightening agent, 56: ammonia gas, 57: ammonium bisulfate, 58: oxygen cleaning tank, 59: solid-liquid separator, 60: cathode copper plate water-washing unit, 61: oxygen oxidation reaction tank, and 62: metal electroextraction cell.

### DETAILED DESCRIPTION OF THE EMBODIMENTS

The present disclosure is further described below through specific examples.

A process for etching a circuit board with alkaline tetraamminecopper (II) sulfate in each example of the present disclosure includes the following steps:

Step 1: A circuit board is etched with an alkaline tetraamminecopper (II) sulfate etching solution in an etching machine. Process parameters of the alkaline tetraamminecopper (II) sulfate etching working solution are shown in Tables 1 and 2, and parameters of an etching-resist layer of the circuit board are shown in Table 3.

Step 2: During an etching process, an etching sub-solution and/or a regenerated etching sub-solution (a composition is shown in Table 2) is/are added to the etching working solution, and the etching working solution is oxidized and regenerated by a copper etching agent-oxidation regeneration reaction supply source, such that pH and ORP values of the etching working solution are maintained within the ranges shown in Table 1.

Step 3: After the etching is completed, a status of the etching-resist layer of the circuit board is examined. Examination results and etching rates are recorded in Table 3.

In each of the following examples and comparative examples, a length*width size of a circuit board is 200 mm*200 mm; and a pressure of a nozzle of an etching production line is 1.3 kg to 3.0 kg.

### Example 1

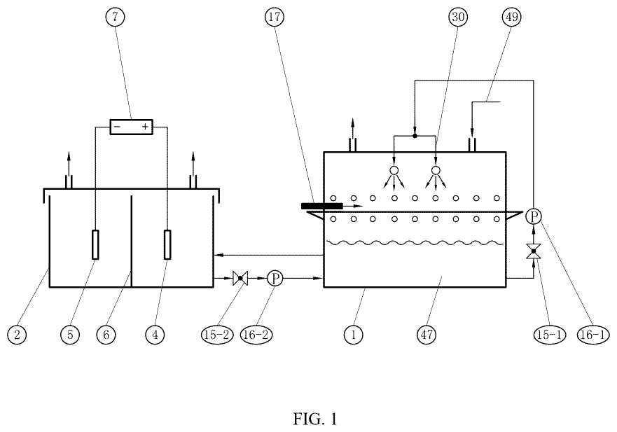

As shown in FIG. 1, an apparatus for etching a circuit board with alkaline tetraamminecopper (II) sulfate is provided, including: an etching machine 1, an oxidation electrolytic cell 2, an electrolytic power supply 7, a valve, and a pump.

Specifically, the etching machine 1 is a spray-type etching machine.

The oxidation electrolytic cell 2 is a copper etching agent-oxidation regeneration reaction supply source, and when the oxidation electrolytic cell conducts electrolysis, an anode of the oxidation electrolytic cell directly electrochemically oxidizes a cuprous ammonia complex in an etching working solution into tetraamminecopper (II) sulfate.

The oxidation electrolytic cell 2 is provided with an electrolytic cell separator 6 configured to divide the oxidation electrolytic cell into an anode cell zone and a cathode cell zone, and an electrolytic anode 4 and an electrolytic cathode 5 are arranged in the anode cell zone and the cathode cell zone, respectively, and are connected to the electrolytic power supply 7. The electrolytic cell separator 6 is an anion exchange membrane, the electrolytic anode 4 is platinum, and the electrolytic cathode 5 is copper.

The anode cell zone of the oxidation electrolytic cell 2 is in liquid flow circulation connection with the etching machine 1 through a pipeline provided with the valve and the pump, such that an etching working solution can circulate between the anode cell zone and the etching machine to maintain a copper etching agent concentration.

An anode electrolyte in the oxidation electrolytic cell 2 is an etching working solution, and a cathode electrolyte in the oxidation electrolytic cell is an ammonium sulfate solution.

The etching machine is provided with a feeding port configured to feed an etching sub-solution 49. The etching sub-solution 49 is a mixed aqueous solution of ammonia water, ammonium sulfate, and ammonium formate.

Before an etching operation begins, an etching solution is fed into the etching machine 1, the pump 16-1 is turned on for etching spray, and a conveyor row wheel is started. According to the above steps, a plurality of circuit boards 17 (etching-resist layers are shown in Table 3) are successively placed in the etching machine for etching, during which an etching sub-solution is added to the etching machine to maintain a stable concentration of each component in an etching working solution.

### Example 2

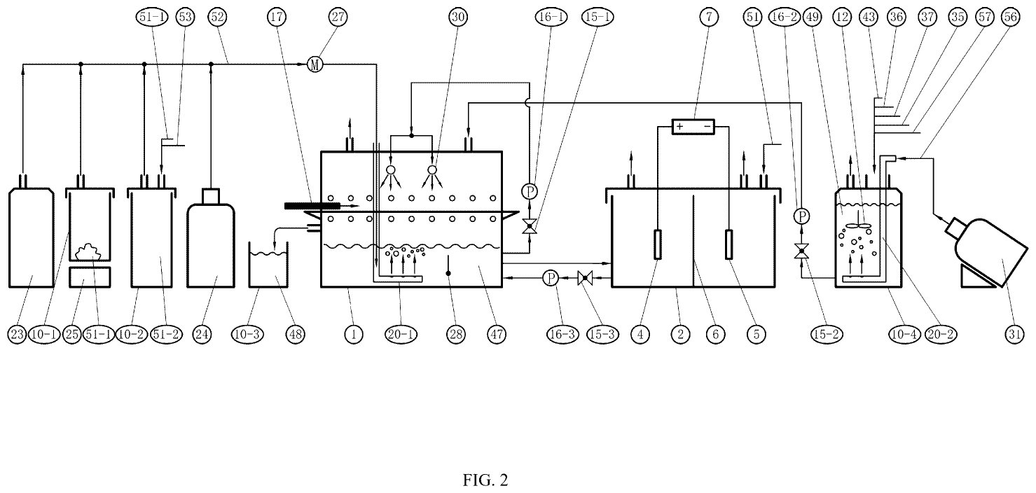

As shown in FIG. 2, an apparatus for etching a circuit board with alkaline tetraamminecopper (II) sulfate is provided, including: an etching machine 1, an oxidation electrolytic cell 2, an electrolytic power supply 7, four temporary storage tanks, an impeller stirrer 12, a molecular sieve oxygen-production machine 23, a commercial oxygen-containing steel cylinder 24, a gas-pressurized pump 27, a sensor 28, a liquid ammonia-containing steel cylinder 37, two pipeline bubbling gas-liquid mixers, a valve, and a pump.

Specifically, in this example, a copper etching agent-oxidation regeneration reaction supply source refers to the oxidation electrolytic cell 2 and oxygen. There are the following four oxygen sources: oxygen in the commercial oxygen-containing steel cylinder 24, oxygen produced by the molecular sieve oxygen-production machine 23, oxygen produced by heating potassium permanganate in a temporary storage tank 10-1, and oxygen produced through a chemical reaction between hydrogen peroxide and manganese dioxide in a temporary storage tank 10-2. The above four oxygen sources all are introduced into an etching working solution 47 in the etching machine 1 through a pipeline bubbling gas-liquid mixer 20-1.

The oxidation electrolytic cell 2 is provided with an electrolytic cell separator 6 configured to divide the oxidation electrolytic cell into an anode cell zone and a cathode cell zone, and an electrolytic anode 4 and an electrolytic cathode 5 are arranged in the anode cell zone and the cathode cell zone, respectively, and are connected to the electrolytic power supply 7. The electrolytic cell separator 6 is an anion exchange membrane, the electrolytic anode 4 is platinum, and the electrolytic cathode 5 is copper. The anode cell zone of the oxidation electrolytic cell 2 is provided with a pipeline in liquid flow circulation connection with the etching machine 1. An anode electrolyte in the oxidation electrolytic cell 2 is an etching working solution, and a cathode electrolyte in the oxidation electrolytic cell is a waste etching solution.

The etching machine 1 is a spray-type etching machine, and the spray-type etching machine is provided with the sensor 28, which is specifically a pH meter. The etching machine 1 is also connected to a temporary storage tank 10-3 to hold a waste etching solution 48.

A temporary storage tank 10-4 is connected to a feeding port of the etching machine, such that an etching sub-solution 49 can be fed. Liquid ammonia (which is fed from the liquid ammonia-containing steel cylinder through a pipeline bubbling gas-liquid mixer 20-2), ammonium sulfate, ammonium bisulfate, ammonium carbonate, ammonium bicarbonate, and ammonia water as chemical raw materials to prepare the etching sub-solution 49 are fed into the temporary storage tank 10-4, and the impeller stirrer 12 is started to prepare the etching sub-solution; and after the preparation is completed, the impeller stirrer and the liquid ammonia-containing steel cylinder are shut down, and the feeding is stopped.

Before an etching operation starts, an etching solution is fed into the etching machine 1, and then a pump 16-1 is turned on for etching spray and a conveyor row wheel is started; and oxygen is introduced into the etching machine by the gas-pressurized pump and the pipeline bubbling gas-liquid mixer 20-1 to allow an oxidation regeneration reaction for the etching working solution. According to the above steps, a plurality of circuit boards 17 (etching-resist layers are shown in Table 3) are successively placed in the etching machine for etching. During an etching process, a pump 16-2 is controlled to feed the etching sub-solution 49 according to a production set value and a measurement result of the pH meter, such that a chemical copper-etching reaction of the etching working solution remains stable.

### Example 3

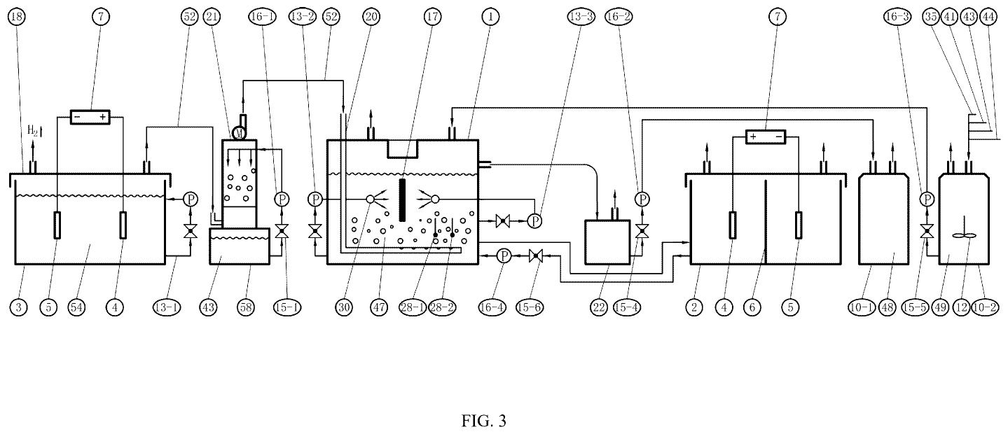

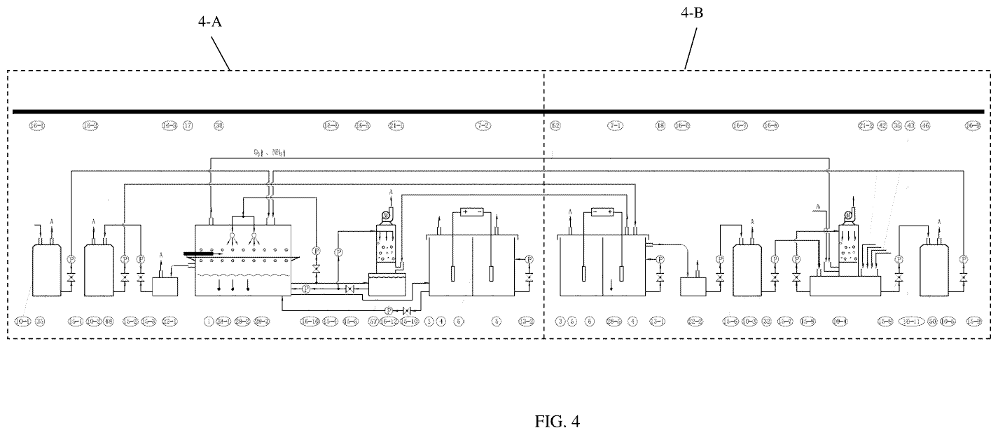

As shown in FIG. 3, an apparatus for etching a circuit board with alkaline tetraamminecopper (II) sulfate is provided, including: an etching machine 1, an oxidation electrolytic cell 2, an oxygen-production electrolytic cell 3, an electrolytic power supply 7, two temporary storage tanks 10, an impeller stirrer 12, a liquid flow stirrer 13, a pipeline bubbling gas-liquid mixer 20, a spray tower-type gas-liquid mixer 21, a liquid flow buffer tank 22, a valve, a pump, and an oxygen cleaning tank 58.

Specifically, the etching machine 1 is an immersion-type etching machine with two liquid flow stirrers, and the immersion-type etching machine is provided with a bubbling gas-liquid mixer 20 and sensors 28-1 and 28-2, where the sensors are specifically a pH meter and an ORP meter.

In this example, a copper etching agent-oxidation regeneration reaction supply source refers to the oxidation electrolytic cell 2 and oxygen.

The oxidation electrolytic cell 2 is provided with an electrolytic cell separator 6 configured to divide the oxidation electrolytic cell into an anode cell zone and a cathode cell zone, and an electrolytic anode 4 and an electrolytic cathode 5 are arranged in the anode cell zone and the cathode cell zone, respectively, and are connected to the electrolytic power supply 7. The electrolytic cell separator 6 is an anion exchange membrane, the electrolytic anode 4 is platinum, and the electrolytic cathode 5 is copper. The anode cell zone of the oxidation electrolytic cell 2 is provided with a pipeline in liquid flow circulation connection with the etching machine. An anode electrolyte in the oxidation electrolytic cell 2 is an etching working solution, and a cathode electrolyte in the oxidation electrolytic cell is a waste etching solution.

In this example, an oxygen source is oxygen produced through electrolysis with the oxygen-production electrolytic cell 3, where an electrolyte solution 54 is a sodium hydroxide solution. In the oxygen-production electrolytic cell 3, an electrolytic anode 4 is gold, an electrolytic cathode 5 is a stainless steel, and the electrolytic anode and the electrolytic cathode are connected to a positive electrode and a negative electrode of the electrolytic power supply, respectively. In addition, a liquid flow stirrer 13-1 is arranged in the oxygen-production electrolytic cell 3 to stir an electrolyte.

Oxygen produced through electrolysis with the oxygen-production electrolytic cell 3 is cleaned with an ammonium sulfate solution in the oxygen cleaning tank 58, and then introduced into an etching working solution 47 in the etching machine 1 through the pipeline bubbling gas-liquid mixer 20.

A temporary storage tank 10-2 is connected to a feeding port of the etching machine, such that an etching sub-solution 49 can be fed. A temporary storage tank 10-1 is connected to an overflow port of the etching machine through the liquid flow buffer tank 22, and is configured to hold a waste etching solution 48.

Before an etching operation starts, an etching solution is fed into the etching machine 1, a plurality of circuit boards 17 (etching-resist layers are shown in Table 3) are successively placed in the etching machine, and etching is conducted according to the above steps. As the etching proceeds, a pump 16-3 is controlled to feed an etching sub-solution according to a production set value and a measurement result of the pH meter, and an operator can control an output size of a working current or a shutdown of the electrolytic power supply 7 according to a value detected by the ORP meter on site.

### Example 4

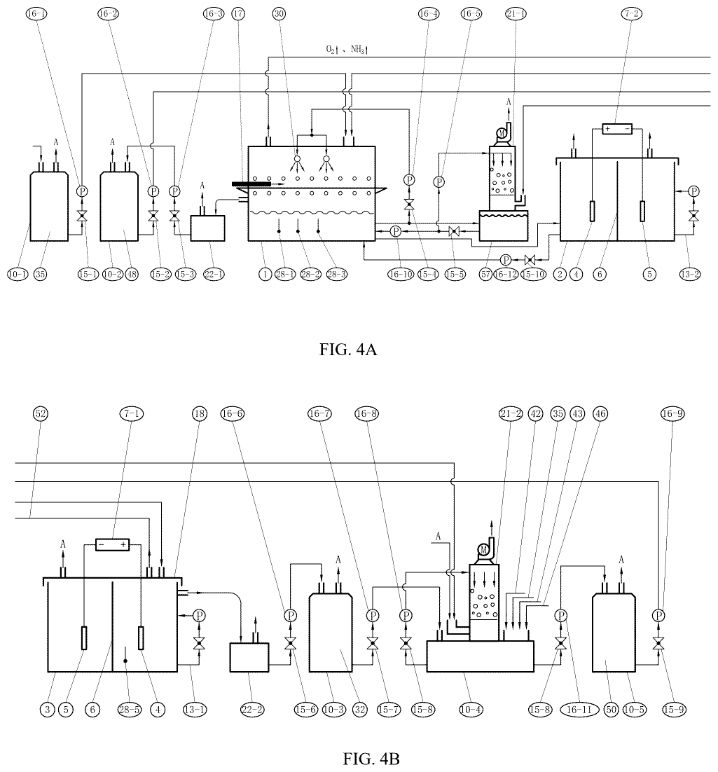

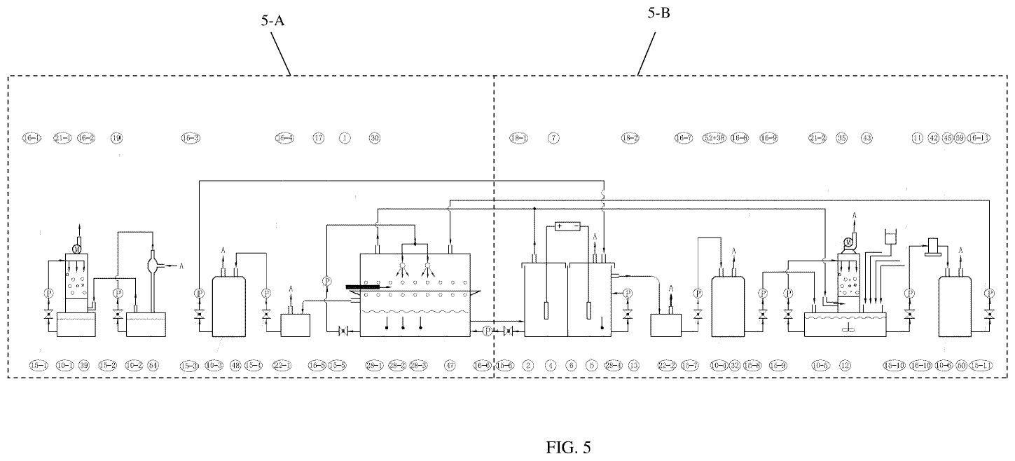

As shown in FIG. 4 and its enlarged views FIG. 4A and FIG. 4B, an apparatus for etching a circuit board with alkaline tetraamminecopper (II) sulfate is provided, including: an etching machine 1, five temporary storage tanks 10, two liquid flow buffer tanks 22, two spray-type gas-liquid mixers 21, an oxidation electrolytic cell 2, an oxygen-production electrolytic cell 3, an electrolytic power supply 7, an oxygen cleaning tank 58, a valve, a pump, and four sensors 28.

Specifically, in this example, a copper etching agent-oxidation regeneration reaction supply source refers to the oxidation electrolytic cell 2 and oxygen produced by the oxygen-production electrolytic cell 3.

The oxidation electrolytic cell 2 is provided with an electrolytic cell separator 6 configured to divide the oxidation electrolytic cell into an anode cell zone and a cathode cell zone. The cathode cell zone is provided with a liquid flow stirrer 13-2. An electrolytic anode 4 and an electrolytic cathode 5 are arranged in the anode cell zone and the cathode cell zone, respectively, and are connected to the electrolytic power supply 7. The electrolytic cell separator 6 is an anion exchange membrane, the electrolytic anode 4 is platinum, and the electrolytic cathode 5 is copper. The anode cell zone of the oxidation electrolytic cell 2 is provided with a pipeline in liquid flow circulation connection with the etching machine. An anode electrolyte in the oxidation electrolytic cell 2 is an etching working solution, and a cathode electrolyte in the oxidation electrolytic cell is a waste etching solution.

The oxygen-production electrolytic cell 3 is provided with a cation exchange membrane as an electrolytic cell separator 6 configured to divide the oxygen-production electrolytic cell into an anode cell zone and a cathode cell zone, where the anode cell zone is provided with a liquid flow stirrer 13-1 and a sensor 28-5 (specifically a gravitometer). In the oxygen-production electrolytic cell 3, an electrolytic anode 4 is conductive graphite and an electrolytic cathode 5 is iron; the electrolytic anode and the electrolytic cathode are located in the anode cell zone and the cathode cell zone and are connected to a positive electrode and a negative electrode of the electrolytic power supply, respectively; and an anode electrolyte and a cathode electrolyte both are a waste etching solution. Oxygen produced in the anode cell zone of the oxygen-production electrolytic cell 3 is introduced into an etching working solution of the etching machine through the oxygen cleaning tank 58.

The etching machine 1 is a spray-type etching machine, and the spray-type etching machine is provided with sensors 28-1, 28-2, and 28-3, which are specifically a pH meter, an ORP meter, and a gravitometer.

A solution 32 produced from a waste etching solution after undergoing copper electroextraction with the oxygen-production electrolytic cell 3 is delivered to a temporary storage tank 10-4 through a liquid flow buffer tank 22-2 and a temporary storage tank 10-3, and then a complexed ammonia supply source and an additive are added to the temporary storage tank 10-4 to prepare a regenerated etching sub-solution. The regenerated etching sub-solution is delivered to and stored in a temporary storage tank 10-5, and then is delivered to a feeding port of the etching machine through a pipeline according to a process setting.

In order to allow the efficient copper electroextraction of the oxygen-production electrolytic cell 3, a feeding amount of a pump 16-6 is controlled through the gravitometer, such that a solution 32 undergoing copper electroextraction that overflows from the anode cell zone still includes a specified amount of copper ions at a concentration of 30 g/L.

In this example, temporary storage tanks 10-1 and 10-2 are further provided. The temporary storage tank 10-1 is configured to temporarily store ammonia water and feed ammonia water to the feeding port of the etching machine. The temporary storage tank 10-2 is configured to temporarily store a waste etching solution, which not only receives a waste etching solution from the etching machine, but also feeds a waste etching solution into the oxygen-production electrolytic cell 3.

Before an etching operation starts, an etching solution is fed into the etching machine 1, and a waste etching solution is fed into each of the cathode and anode cell zones of the oxygen-production electrolytic cell 3; the etching machine and all other devices are started, and a plurality of circuit boards 17 (etching-resist layers are shown in Table 3) are successively placed in the etching machine; and etching is conducted according to the above steps.

During an operation of the oxygen-production electrolytic cell 3, a cuprous ammonia complex Cu₂(NH₃)₄SO₄ undergoes an oxidation reaction and oxygen is produced in the anode cell zone, and copper is precipitated on the electrolytic cathode. According to a measurement result of the gravitometer in the anode cell zone and a process set value, a pump 16-2 is controlled to feed a waste etching solution into the anode cell zone of the oxygen-production electrolytic cell, and a solution overflowing from the anode cell zone is pumped through the liquid flow buffer tank 22-2 to and temporarily stored in the temporary storage tank 10-3.

Oxygen escaping from the oxygen-production electrolytic cell is drained by the spray-type gas-liquid mixer 21-1 to be mixed with an etching working solution to allow a reaction. During an etching process, according to a production set value and a measurement result of the pH meter, a pump 16-1 is controlled to feed ammonia water in the temporary storage tank 10-1 into an etching working solution; according to a production set value and a measurement result of the ORP meter, a size of an output current or a shutdown of the electrolytic power supply is controlled to control an output of oxygen; and according to a production set value and a measurement result of the gravitometer in the etching machine, a pump 16-9 is controlled to feed a regenerated etching sub-solution into the etching machine to maintain the balance of components in an etching working solution.

### Example 5

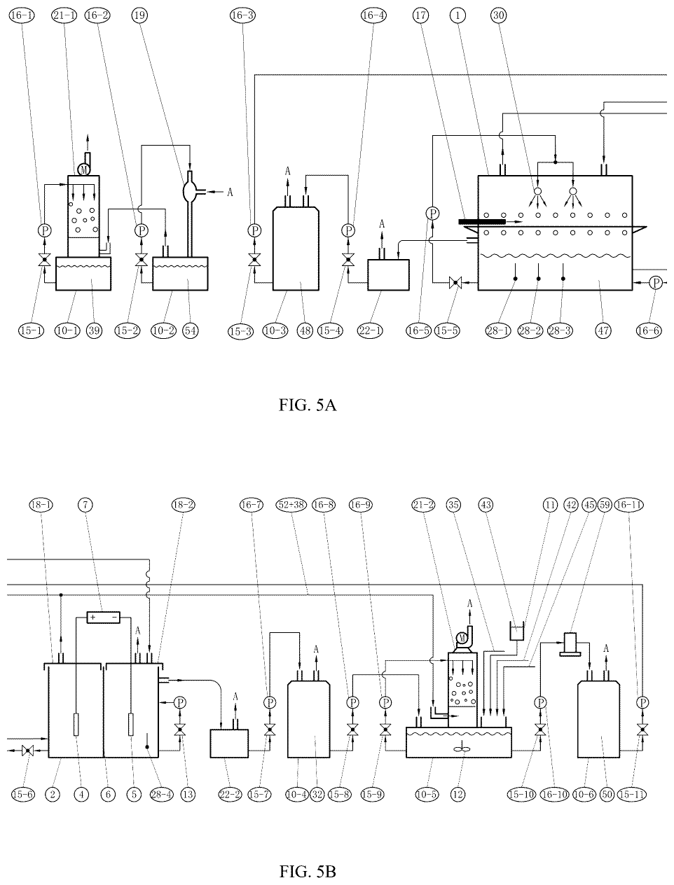

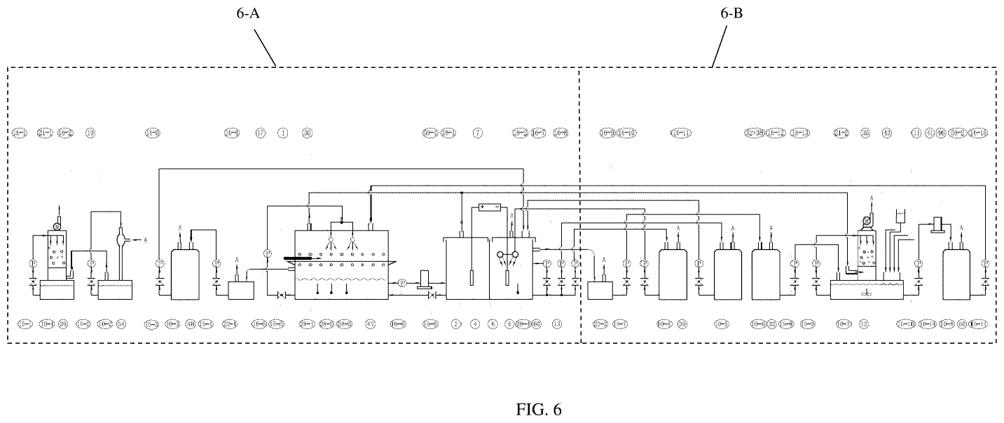

As shown in FIG. 5 and its enlarged views FIG. 5A and FIG. 5B, an apparatus for etching a circuit board with alkaline tetraamminecopper (II) sulfate is provided, including: an etching machine 1, six temporary storage tanks 10, a liquid flow stirrer 13, two spray-type gas-liquid mixers 21, two liquid flow buffer tanks 22, an oxidation electrolytic cell 2, an electrolytic power supply 7, a solid-liquid separator 59, four sensors 28, a valve, and a pump.

In this example, a copper etching agent-oxidation regeneration reaction supply source is the oxidation electrolytic cell 2. In the oxidation electrolytic cell 2, an anode electrolyte is an etching working solution, and a cathode electrolyte is a waste etching solution. When the oxidation electrolytic cell conducts electrolysis, an anode of the oxidation electrolytic cell directly electrochemically oxidizes a cuprous ammonia complex in an etching working solution into tetraamminecopper (II) sulfate.

The oxidation electrolytic cell 2 is provided with an electrolytic cell separator 6 configured to divide the oxidation electrolytic cell into an anode cell zone and a cathode cell zone, and an electrolytic anode 4 and an electrolytic cathode 5 are arranged in the anode cell zone and the cathode cell zone, respectively, and are connected to the electrolytic power supply 7. The electrolytic cell separator 6 is an anion exchange membrane, the electrolytic anode 4 is platinum, and the electrolytic cathode 5 is copper. The anode cell zone of the oxidation electrolytic cell is provided with a pipeline in liquid flow circulation connection with the etching machine, and the cathode cell zone of the oxidation electrolytic cell is provided with a liquid flow stirrer 13 and a sensor 28-4.

A solution 32 produced from a waste etching solution after undergoing copper electroextraction in the cathode cell zone of the oxidation electrolytic cell 2 is delivered to a temporary storage tank 10-5 through a liquid flow buffer tank 22-2 and a temporary storage tank 10-4, then a complexed ammonia supply source and an additive are added to the temporary storage tank 10-5, and a resulting mixed solution is mixed by the supporting gas-liquid mixer 21-2 and impeller stirrer 12 to prepare a regenerated etching sub-solution. The regenerated etching sub-solution is treated by the solid-liquid separator 59, then delivered to and stored in a temporary storage tank 10-6, and then delivered to a feeding port of the etching machine through a pipeline according to a process setting.

The etching machine 1 is a spray-type etching machine, and the spray-type etching machine is provided with sensors 28-1, 28-2, and 28-3.

The sensor 28-1 is a pH meter, the sensors 28-2 and 28-4 are gravitometers, and the sensor 28-3 is an ORP meter.

In this example, a temporary storage tank 10-3 is provided and is connected to the etching machine 1 through a liquid flow buffer tank 22-1, and the temporary storage tank 10-3 not only receives a waste etching solution from the etching machine, but also feeds a waste etching solution into the oxidation electrolytic cell 2.

The apparatus in this example is further provided with a tail gas treatment device including a temporary storage tank 10-1, a vacuum ejector 19, a temporary storage tank 10-2, and a spray-type gas-liquid mixer 21-1, and the tail gas treatment device is configured to receive and eco-friendly treat a gas escaping from the oxidation electrolytic cell and other temporary storage tanks. Clear water is stored in the temporary storage tank 10-1, and sulfuric acid is stored in the temporary storage tank 10-2.

Before etching starts, an etching solution is fed into the etching machine and the anode cell zone of the oxidation electrolytic cell, and a waste etching solution in the temporary storage tank 10-3 is fed into the cathode cell zone of the oxidation electrolytic cell; and a plurality of circuit boards 17 (etching-resist layers are shown in Table 3) are successively placed in the etching machine. A pump 16-5 is started to make an etching working solution flow in a spray circulation manner, a pump 16-6 is started to make an etching working solution circulate between the etching machine and the anode cell zone, a pump 16-9 is started to make the gas-liquid mixer 21-2 operate normally, and the electrolytic power supply 7 is started to make the oxidation electrolytic cell conduct electrolysis.

During an etching process, the pH meter and the gravitometer are configured to monitor a pH and a specific gravity of an etching working solution, respectively, and according to detection results and process set values, a pump 16-11 is controlled to feed a regenerated etching sub-solution, such that the etching working solution can allow stable etching. The ORP meter is configured to monitor an ORP value of an etching working solution, and accordingly, a size of a working current or a shutdown of the electrolytic power supply 7 is controlled. A gravitometer is arranged in the cathode cell zone of the oxidation electrolytic cell, and according to a detection result of the gravitometer and a process set copper ion concentration in the cathode electrolyte, a pump 16-3 is controlled to feed a waste etching solution in the temporary storage tank 10-3 into the cathode cell zone of the oxidation electrolytic cell, such that the electrolytic anode normally electrochemically oxidize a cuprous ammonia complex in an etching working solution and the electrolytic cathode precipitates metallic copper.

### Example 6

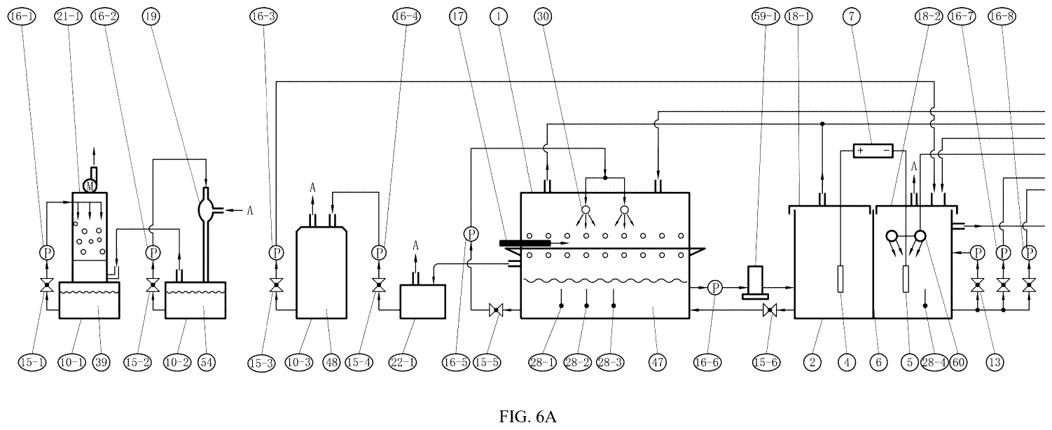

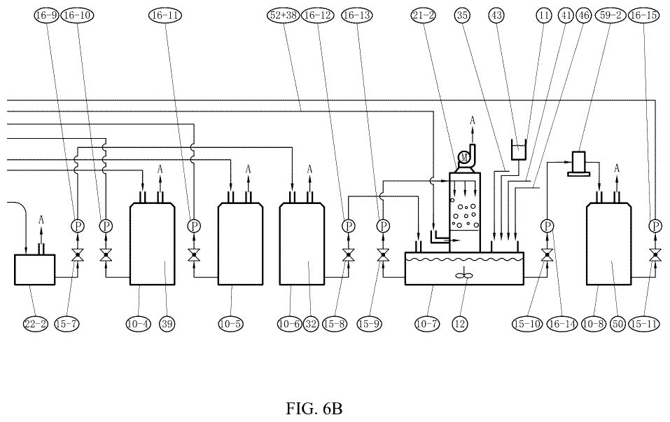

As shown in FIG. 6 and its enlarged views FIG. 6A and FIG. 6B, an apparatus for etching a circuit board with alkaline tetraamminecopper (II) sulfate is provided, including: an etching machine 1, eight temporary storage tanks 10, a liquid flow stirrer 13, two spray-type gas-liquid mixers 21, two liquid flow buffer tanks 22, an oxidation electrolytic cell 2, an electrolytic power supply 7, two solid-liquid separators 59, four sensors 28, a cathode copper plate water-washing unit 60, a valve, and a pump.

In this example, a copper etching agent-oxidation regeneration reaction supply source is the oxidation electrolytic cell 2. The oxidation electrolytic cell 2 is provided with an electrolytic cell separator 6 configured to divide the oxidation electrolytic cell into an anode cell zone and a cathode cell zone. The cathode cell zone is provided with a liquid flow stirrer 13 and a sensor 28-4. An electrolytic anode 4 and an electrolytic cathode 5 are arranged in the anode cell zone and the cathode cell zone, respectively, and are connected to the electrolytic power supply 7. The electrolytic cell separator 6 is a reverse osmosis membrane, the electrolytic anode 4 is an insoluble anode with a titanium-based coating, and the electrolytic cathode 5 is titanium. In the oxidation electrolytic cell 2, an anode electrolyte is an etching working solution and a cathode electrolyte is a waste etching solution (that is, copper electroextraction is conducted in the cathode cell zone, and the oxidation electrolytic cell 2 also serves as a metal electroextraction cell).

The etching machine 1 is connected to the anode cell zone of the oxidation electrolytic cell 2 through a liquid flow circulation pipeline. When the oxidation electrolytic cell conducts electrolysis, an anode of the oxidation electrolytic cell directly oxidizes a cuprous ammonia complex in an etching working solution into tetraamminecopper (II) sulfate.

A solution 32 produced from a waste etching solution after undergoing copper electroextraction in the cathode cell zone of the oxidation electrolytic cell 2 is delivered to a temporary storage tank 10-7 through a liquid flow buffer tank 22-2 and a temporary storage tank 10-6, then a complexed ammonia supply source and an additive are added to the temporary storage tank 10-7, and a resulting mixed solution is mixed by the supporting gas-liquid mixer 21-2 and impeller stirrer 12 to prepare a regenerated etching sub-solution. The regenerated etching sub-solution is treated by the solid-liquid separator 59-2, then delivered to and stored in a temporary storage tank 10-8, and then delivered to a feeding port of the etching machine through a pipeline according to a process setting.

The cathode copper plate water-washing unit 60 includes a nozzle in the cathode cell zone of the oxidation electrolytic cell 2, a temporary storage tank 10-4, and a temporary storage tank 10-5, where clear water 39 is stored in the temporary storage tank 10-4 and the cathode electrolyte is temporarily stored in the temporary storage tank 10-5.

The etching machine 1 is a spray-type etching machine, and the spray-type etching machine is provided with sensors 28-1, 28-2, and 28-3.

The sensor 28-1 is a pH meter, the sensors 28-2 and 28-4 are gravitometers, and the sensor 28-3 is an ORP meter.

In this example, a temporary storage tank 10-3 is provided and is connected to the etching machine 1 through a liquid flow buffer tank 22-1, and the temporary storage tank 10-3 not only receives a waste etching solution from the etching machine, but also feeds a waste etching solution into the oxidation electrolytic cell 2.

The apparatus in this example is further provided with a tail gas treatment device including a temporary storage tank 10-1, a vacuum ejector 19, a temporary storage tank 10-2, and a spray-type gas-liquid mixer 21-1, and the tail gas treatment device is configured to receive and eco-friendly treat a gas escaping from the oxidation electrolytic cell and other temporary storage tanks, where clear water is stored in the temporary storage tank 10-1 and formic acid is stored in the temporary storage tank 10-2.

Before etching starts, an etching solution is fed into the etching machine and the anode cell zone of the oxidation electrolytic cell, and a waste etching solution in the temporary storage tank 10-3 is fed into the cathode cell zone of the oxidation electrolytic cell; and a plurality of circuit boards 17 (etching-resist layers are shown in Table 3) are successively placed in the etching machine. A pump 16-5 is started to make an etching working solution flow in a spray circulation manner. A pump 16-6 is started to make an etching working solution in the etching machine pumped through a solid-liquid separator 59-1 to the anode cell zone of the oxidation electrolytic cell for circulation. A pump 16-13 is started to make the gas-liquid mixer 21-2 operate normally. The electrolytic power supply 7 is started to make the oxidation electrolytic cell conduct electrolysis. When copper electroextraction in the cathode cell zone is completed, the cathode electrolyte is pumped by a pump 16-7 to the temporary storage tank 10-5 for temporary storage. Then a pump 16-10 is started to spray the clear water in the temporary storage tank 10-4 onto a cathode copper plate for cleaning, and after the cleaning is completed, the cathode copper plate is taken out. A cleaning waste liquid in the cathode cell zone is pumped by a pump 16-8 back to the temporary storage tank 10-4. A pump 16-11 is started to deliver a solution in the temporary storage tank 10-5 to the cathode cell zone, and the cathode and a tank cover are placed back to further allow electrolysis. This operation procedure can reduce the ammonia pollution caused by the operation of directly taking the cathode copper plate out from an electrolyte.

During an electrolysis operation, the electrolytic anode of the oxidation electrolytic cell normally electrochemically oxidizes a cuprous ammonia complex in an etching working solution and produces oxygen, and the electrolytic cathode precipitates metallic copper.

During an etching process, the pH meter and the gravitometer are configured to monitor a pH and a specific gravity of an etching working solution, respectively, and according to detection results and process set values, a pump 16-15 is controlled to feed a regenerated etching sub-solution, such that the etching working solution can allow stable etching. The ORP meter is configured to monitor an ORP value of an etching working solution, and accordingly, a size of a working current or a shutdown of the electrolytic power supply 7 is controlled. A gravitometer is arranged in the cathode cell zone of the oxidation electrolytic cell, and according to a detection result of the gravitometer and a process set copper ion concentration in the cathode electrolyte, a pump 16-3 is controlled to feed a waste etching solution in the temporary storage tank 10-3 into the cathode cell zone of the oxidation electrolytic cell.

### Example 7

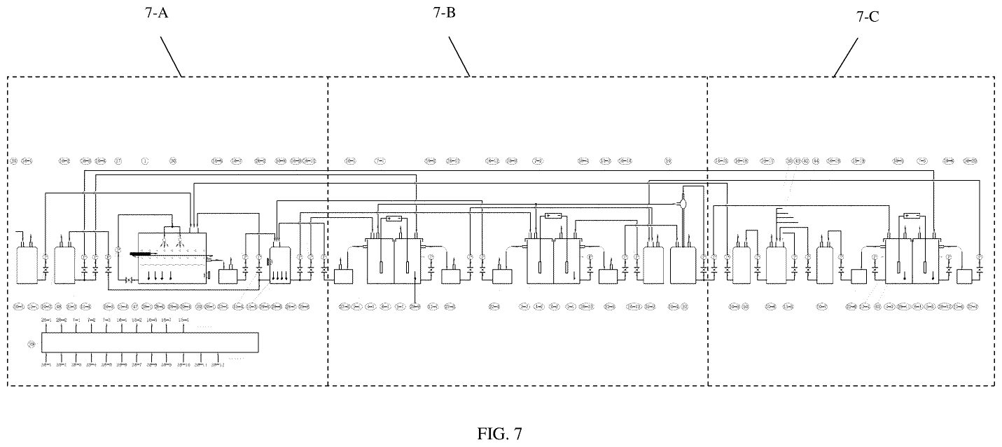

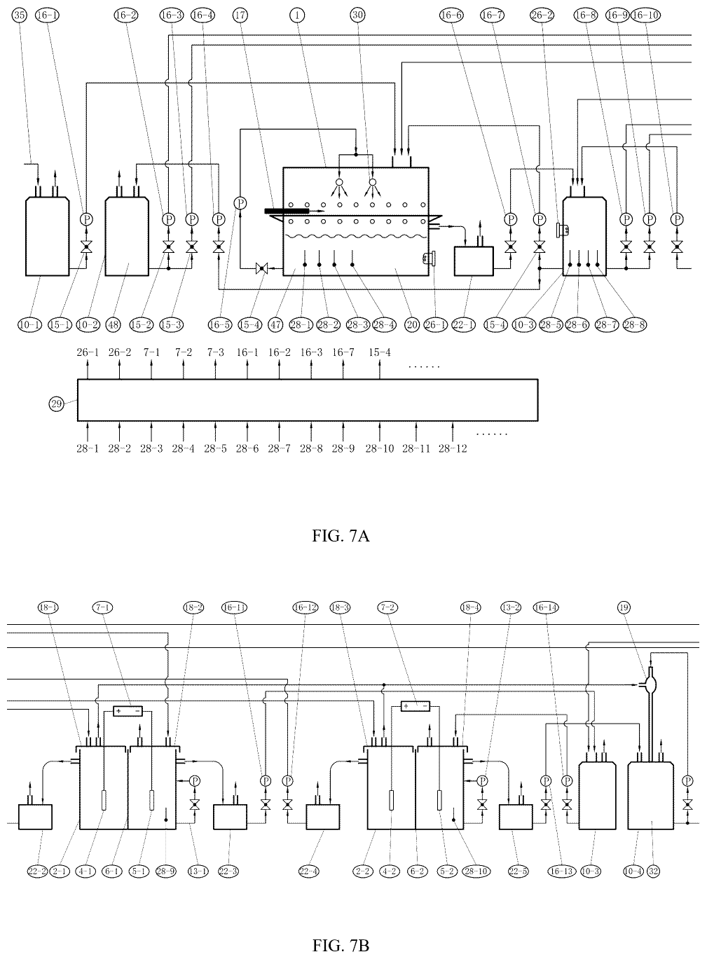

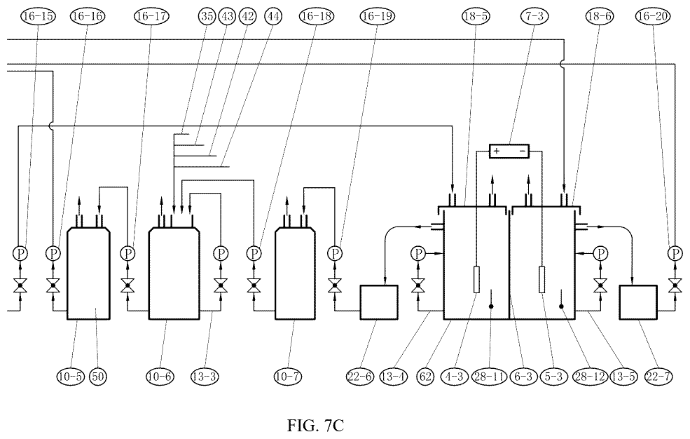

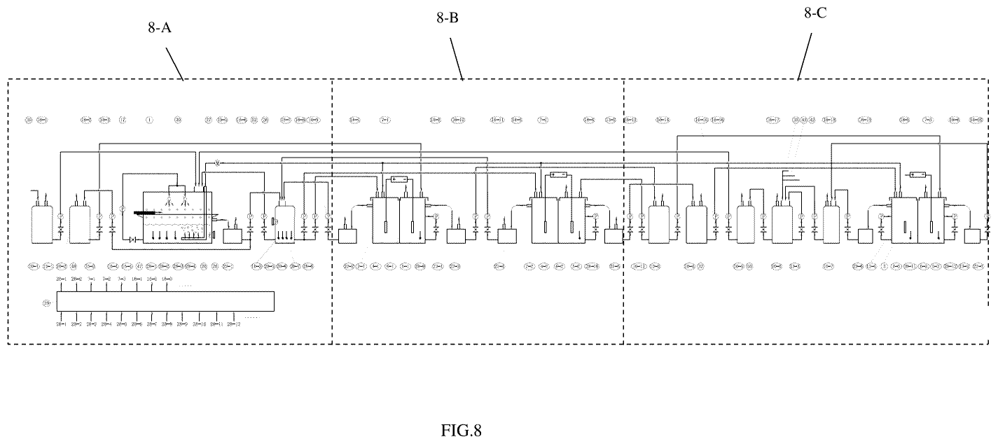

As shown in FIG. 7 and its enlarged views FIG. 7A, FIG. 7B and FIG. 7C, an apparatus for etching a circuit board with alkaline tetraamminecopper (II) sulfate is provided, including: an etching machine 1, seven temporary storage tanks 10, five liquid flow stirrers 13, a vacuum ejector 19, seven liquid flow buffer tanks 22, two oxidation electrolytic cells 2, three electrolytic power supplies 7, two heat exchangers 26, twelve sensors 28, an automatic program controller 29, a plurality of valves and pumps, and a metal electroextraction cell 62. A temporary storage tank 10-3 serves as a mixing-exchange tank.

In this example, a copper etching agent-oxidation regeneration reaction supply source refers to the two oxidation electrolytic cells 2-1 and 2-2. The two oxidation electrolytic cells each are provided with an electrolytic cell separator configured to divide the oxidation electrolytic cell into an anode cell zone and a cathode cell zone. The cathode cell zone is provided with a liquid flow stirrer and a sensor. An electrolytic anode and an electrolytic cathode are arranged in the anode cell zone and the cathode cell zone, respectively, and are connected to an electrolytic power supply. The electrolytic cell separator 6-1 is a reverse osmosis membrane, the electrolytic cell separator 6-2 is a bipolar membrane, the electrolytic anode is an insoluble anode with a titanium-based coating, and the electrolytic cathode is a stainless steel. In each of the oxidation electrolytic cells, an anode electrolyte is an etching working solution and a cathode electrolyte is a waste etching solution.

Anode cell zones of the oxidation electrolytic cells 2-1 and 2-2 each are connected to the temporary storage tank 10-3 through a liquid flow circulation pipeline. The etching machine 1 is also connected to the temporary storage tank 10-3 through a liquid flow circulation pipeline, such that an etching working solution and electrolytes in the two anode cell zones are mixed and exchanged in the temporary storage tank 10-3, and electrolytic anodes of the two oxidation electrolytic cells directly electrochemically oxidize a cuprous ammonia complex in the etching working solution to supplement a copper etching agent in the etching working solution.

Oxygen produced in anode cell zones of the two oxidation electrolytic cells 2-1 and 2-2 and the metal electroextraction cell 62 is introduced into the vacuum ejector 19 to undergo an oxidation reaction with a solution 32 produced after copper electroextraction in a temporary storage tank 10-4.

The etching machine 1 is a spray-type etching machine, and the spray-type etching machine is provided with sensors 28-1, 28-2, 28-3, and 28-4.

In this example, copper is extracted through progressive electrolysis, and the two oxidation electrolytic cells and the metal electroextraction cell all serve as metal electroextraction cells, where the oxidation electrolytic cell 2-1 and the metal electroextraction cell 62 constitute a grade-A metal electroextraction cell, and the oxidation electrolytic cell 2-2 serves as a grade-B metal electroextraction cell. A cathode cell zone of the grade-A metal electroextraction cell is configured to reduce a copper etching agent concentration in a waste etching solution, and after the copper etching agent concentration meets a process requirement, a cathode electrolyte overflowing from the grade-A metal electroextraction cell is fed into a cathode cell zone of the grade-B metal electroextraction cell for copper electroextraction.

The metal electroextraction cell 62 is provided with an electroextraction cell separator to divide the metal electroextraction cell into an anode cell zone and a cathode cell zone, where the electroextraction cell separator 6-3 is a cation exchange membrane, an electrolytic anode is an insoluble anode with a titanium-based coating, and an electrolytic cathode is a stainless steel. The anode and cathode cell zones each are provided with ORP meters 28-11 and 28-12. The anode cell zone is configured to oxidize a solution overflowing from a cathode of the oxidation electrolytic cell 2-2 to prepare a regenerated etching sub-solution 50.

The sensor 28-1 and a sensor 28-5 are pH meters, the sensor 28-2 and a sensor 28-10 are gravitometers, the sensor 28-3, a sensor 28-7, a sensor 28-9, a sensor 28-11, and a sensor 28-12 are ORP meters, the sensor 28-4 and a sensor 28-8 are thermometers, and a sensor 28-6 is a liquid level meter. Data of all sensors are transmitted to the automatic program controller 29 for processing, such that the apparatus operates normally according to a set program.

Before etching starts, an etching working solution is fed into the etching machine, the mixing-exchange tank, and anode cell zones of the oxidation electrolytic cells, where a waste etching solution in a temporary storage tank 10-2 is fed into the cathode cell zone of the grade-A metal electroextraction cell, and a solution overflowing from a cathode electrolyte of the grade-A metal electroextraction cell is fed into a cathode cell zone of the grade-B metal electroextraction cell; a plurality of circuit boards 17 (etching-resist layers are shown in Table 3) are successively placed in the etching machine; and a pump 16-5 is started to make an etching working solution flow in a spray circulation manner, pumps 16-8 and 16-9 are started to make a solution in the mixing-exchange tank circulate between the mixing-exchange tank and the anode cell zones of the two oxidation electrolytic cells, and an electrolytic power supply 7-1 and an electrolytic power supply 7-2 are started to make the two oxidation electrolytic cells conduct electrolysis, respectively.

A copper etching agent concentration in the solution in the mixing-exchange tank is set to be higher than a copper etching agent concentration in the etching working solution. When an ORP value of the sensor 28-3 of the etching machine is lower than a process set value, a rotational speed of the pump 16-7 or a gate valve opening of a valve 15-4 is controlled to control a flow rate for delivering the solution in the mixing-exchange tank to the etching machine, so as to maintain normal etching. An overflow solution from the etching machine flows into a liquid flow buffer tank 22-1 and is pumped back to the mixing-exchange tank for circulation.

When a liquid level in the mixing-exchange tank reaches a set point of a liquid level meter 28-6, a pump 16-4 is started to pump a part of a solution in the temporary storage tank 10-3 to the temporary storage tank 10-2, and this part of the solution is temporarily stored as a waste etching solution.

During an etching process, when it is determined according to a pH detection result of the sensor 28-1 and a process set feeding value that an on-site detection result is lower than a set value, the automatic program controller 29 controls a pump 16-16 and a metering pump 16-1 to feed ammonia water according to a specific gravity detection result of the sensor 28-2, where a feeding amount of the ammonia water can be adjusted on the metering pump 16-1. According to a specific gravity detection result of the sensor 28-2 and a process set value, the pump 16-16 is controlled to feed a regenerated etching sub-solution, such that the etching working solution allows stable etching production. The sensor 28-7 (an ORP meter) arranged on the mixing-exchange tank transmits an ORP value of a mixed solution to the automatic program controller 29 for processing to control a size of a working current or a shutdown of the electrolytic power supply 7-1 and the electrolytic power supply 7-2.

### Example 8

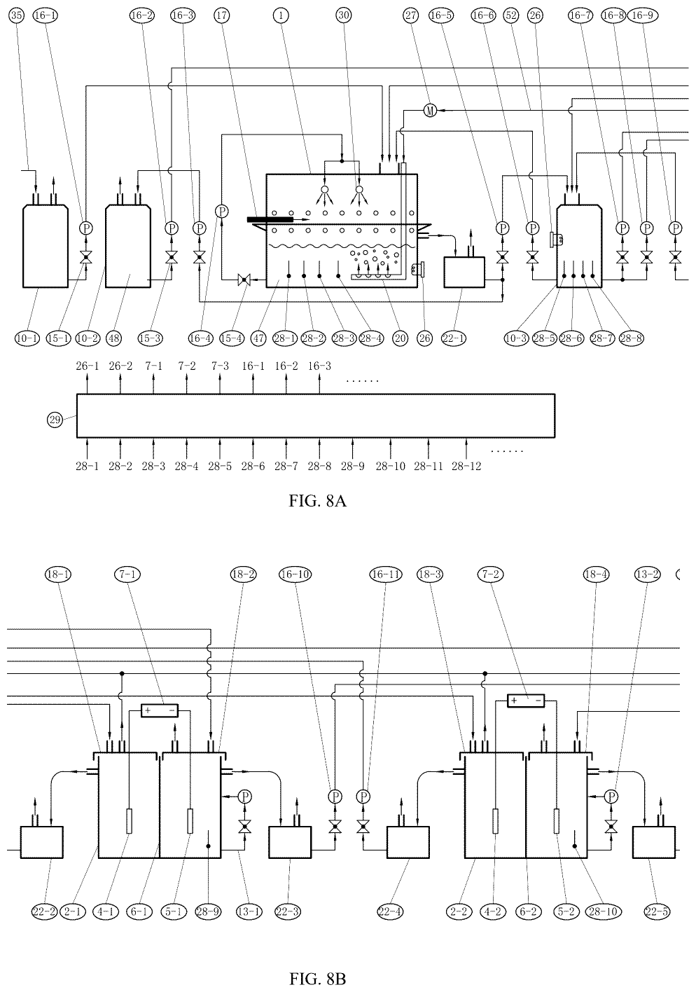

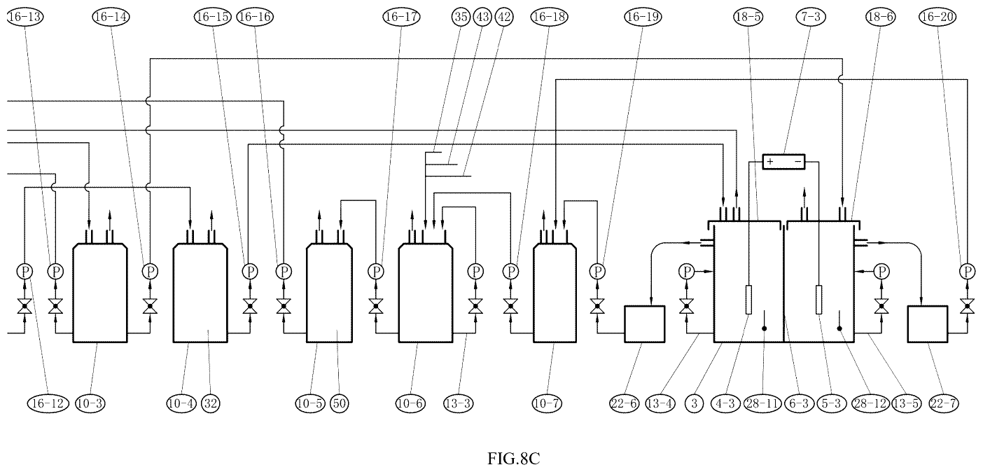

As shown in FIG. 8 and its enlarged views FIG. 8A, FIG. 8B and FIG. 8C, an apparatus for etching a circuit board with alkaline tetraamminecopper (II) sulfate is provided, including: an etching machine 1, seven temporary storage tanks 10, five liquid flow stirrers 13, a pipeline bubbling gas-liquid mixer 20, seven liquid flow buffer tanks 22, a gas-pressurized pump 27, two oxidation electrolytic cells 2, three electrolytic power supplies 7, two heat exchangers 26, twelve sensors 28, an automatic program controller 29, an oxygen-production electrolytic cell 3, and a plurality of valves and pumps. A temporary storage tank 10-3 serves as a mixing-exchange tank.

In this example, a copper etching agent-oxidation regeneration reaction supply source refers to oxidation electrolytic cells 2-1 and 2-2 and oxygen produced in each electrolytic cell of a system.

The oxidation electrolytic cells 2-1 and 2-2 and the oxygen-production electrolytic cell 3 each are provided with an electrolytic cell separator to divide a corresponding electrolytic cell into an anode cell zone and a cathode cell zone, where an electrolytic cell separator 6-1 is a reverse osmosis membrane, an electrolytic cell separator 6-2 is a bipolar membrane, and an electrolytic cell separator 6-3 is a cation exchange membrane.

Anode cell zones of the oxidation electrolytic cells 2-1 and 2-2 each are connected to the mixing-exchange tank through a liquid flow circulation pipeline, and the etching machine 1 is also connected to the mixing-exchange tank through a liquid flow circulation pipeline, such that an etching working solution and electrolytes in the two anode cell zones are mixed and exchanged in the mixing-exchange tank, and electrolytic anodes of the two oxidation electrolytic cells directly electrochemically oxidize a cuprous ammonia complex in the etching working solution to supplement a copper etching agent in the etching working solution.

In this example, copper is extracted through progressive electrolysis, where the oxidation electrolytic cell 2-1 serves as a grade-A metal electroextraction cell, and the oxidation electrolytic cell 2-2 and the oxygen-production electrolytic cell 3 constitute a grade-B metal electroextraction cell. A cathode cell zone of the grade-A metal electroextraction cell is configured to reduce a copper etching agent concentration in a waste etching solution, and after the copper etching agent concentration meets a process requirement, a cathode electrolyte overflowing from the grade-A metal electroextraction cell is fed into a cathode cell zone of the grade-B metal electroextraction cell for copper electroextraction. In addition, a cathode electrolyte overflowing from the oxidation electrolytic cell 2-2 is fed into an anode cell zone of the oxidation electrolytic cell 2-3 for oxidation.

A temporary storage tank 10-6 is configured to receive an anode electrolyte and a cathode electrolyte from the oxygen-production electrolytic cell 3 and prepare a regenerated etching sub-solution.

Oxygen produced in anode cell zones of the oxidation electrolytic cell 2-1, the oxidation electrolytic cell 2-2, and the oxygen-production electrolytic cell 3 is introduced into the etching machine to make an etching working solution rich in oxygen, and the oxygen can react with metallic copper in the etching working solution to accelerate etching, thereby improving an etching production efficiency.

The etching machine 1 is a spray-type etching machine, and the spray-type etching machine is provided with sensors 28-1, 28-2, 28-3, and 28-4. The temporary storage tank 10-3 as a mixing-exchange tank is provided with a sensor 28-5, a sensor 28-6, a sensor 28-7, and a sensor 28-8.

The sensor 28-1 and the sensor 28-5 are pH meters, the sensor 28-2, a sensor 28-10, and a sensor 28-12 are gravitometers, the sensor 28-3, the sensor 28-7, a sensor 28-9, and a sensor 28-11 are ORP meters, the sensor 28-4 and the sensor 28-8 are thermometers, and the sensor 28-6 is a liquid level meter. Data of all sensors are transmitted to the automatic program controller 29 for processing, such that the apparatus operates normally according to a set program.

An etching working solution is fed into the etching machine, the mixing-exchange tank, and anode cell zones of the oxidation electrolytic cells 2-1 and 2-2, where a waste etching solution is fed from a temporary storage tank 10-2 to a cathode cell zone of the oxidation electrolytic cell 2-1, and a cathode electrolyte overflowing from the oxidation electrolytic cell 2-1 is fed into cathode cell zones of the oxidation electrolytic cell 2-2 and the oxygen-production electrolytic cell 3; a plurality of circuit boards 17 (etching-resist layers are shown in Table 3) are successively placed in the etching machine; and a pump 16-4 is started to make an etching working solution flow in a spray circulation manner, pumps 16-7 and 16-8 are started to make a solution in the mixing-exchange tank circulate between the mixing-exchange tank and the anode cell zones of the oxidation electrolytic cells 2-1 and 2-2, and an electrolytic power supply 7-1 and an electrolytic power supply 7-2 are started to make the oxidation electrolytic cells 2-1 and 2-2 conduct electrolysis, respectively.

A cathode electrolyte of the oxidation electrolytic cell 2-1 is detected by the sensor 28-9 (an ORP meter) to reduce the precipitation of copper at a cathode 5-1.

Oxygen produced in an anode cell zone of an oxidation electrolytic cell is introduced into the pipeline bubbling gas-liquid mixer 20 through the gas-pressurized pump 27, such that an etching working solution is rich in oxygen.

In the oxygen-production electrolytic cell 3, an anode cell zone is provided with a sensor 28-11 (an ORP meter), a cathode cell zone is provided with a sensor 28-12 (a gravitometer), and an anode electrolyte is a cathode electrolyte overflowing from the oxidation electrolytic cell 2-2 after copper extraction.

A copper etching agent concentration in a solution in the mixing-exchange tank is set to be higher than a copper etching agent concentration in the etching working solution. When a detection result of the sensor 28-3 (an ORP meter) of the etching machine is lower than a process set value, a rotational speed of the pump 16-6 is controlled to control the pumping of the solution in the mixing-exchange tank to the etching machine, so as to maintain normal etching. An overflow solution from the etching machine flows into a liquid flow buffer tank 22-1 and is pumped back to the mixing-exchange tank for circulation.

When a liquid level in the mixing-exchange tank reaches a set point of the sensor 28-6 (a liquid level meter), a pump 16-3 is started and a pump 16-5 is shut down, such that a solution in the liquid flow buffer tank 22-1 is pumped into the temporary storage tank 10-2; and after the liquid level in the mixing-exchange tank is not at the set point, the pump 16-5 is re-started.

The sensor 28-7 (an ORP meter) arranged on the mixing-exchange tank transmits an ORP value of a mixed solution to the automatic program controller 29 for processing to control a size of a working current or a shutdown of the electrolytic power supply 7-1 and the electrolytic power supply 7-2.

### Example 9

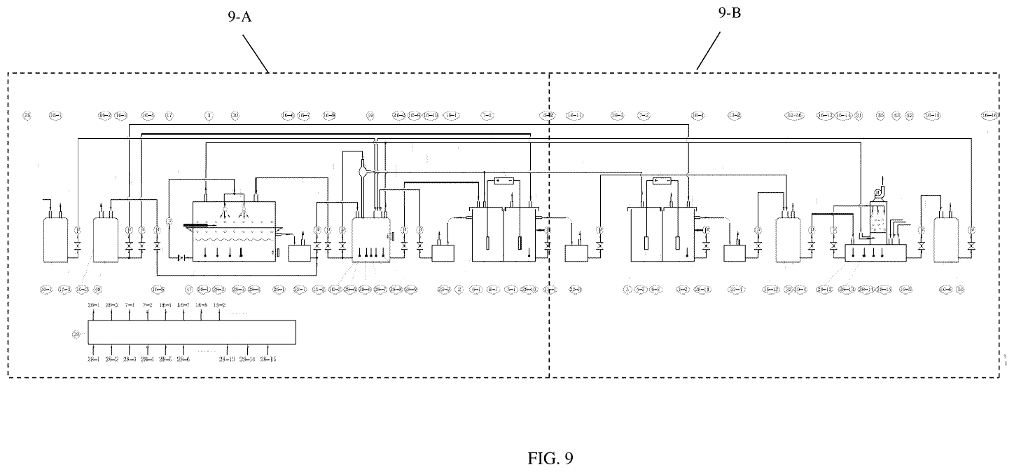

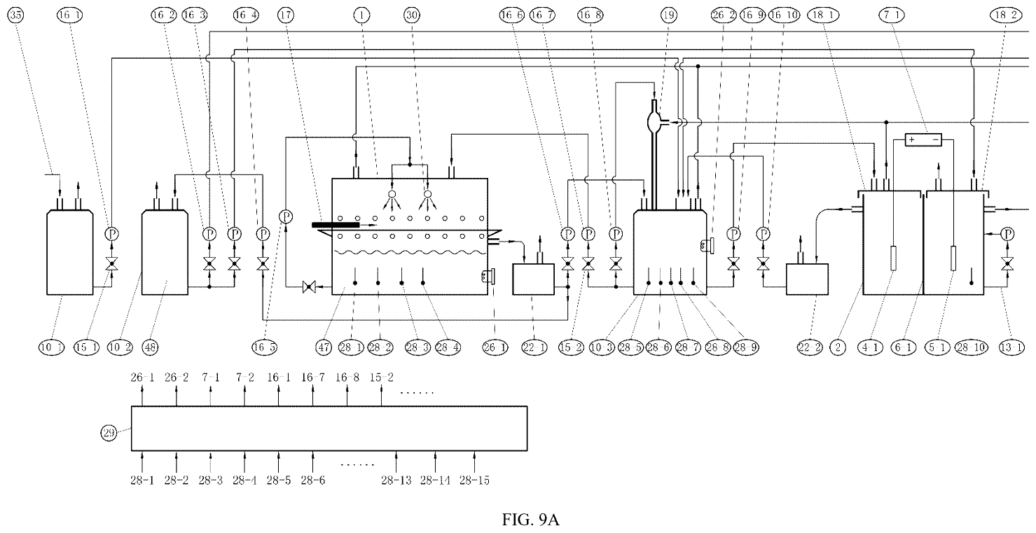

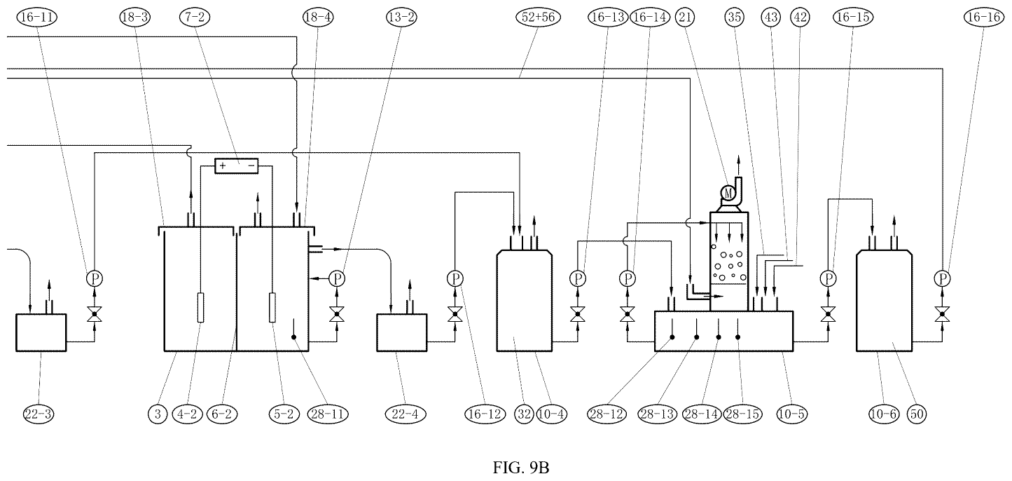

As shown in FIG. 9 and its enlarged views FIG. 9A and FIG. 9B, an apparatus for etching a circuit board with alkaline tetraamminecopper (II) sulfate is provided, including: an etching machine 1, five temporary storage tanks 10, two liquid flow stirrers 13, a vacuum ejector 19, a spray-type gas-liquid mixer 21, four liquid flow buffer tanks 22, an oxidation electrolytic cell 2, an oxygen-production electrolytic cell 3, two electrolytic power supplies 7, two heat exchangers 26, fifteen sensors 28, an automatic program controller 29, a valve, and a pump. A temporary storage tank 10-3 serves as a mixing-exchange tank.

In this example, a copper etching agent-oxidation regeneration reaction supply source refers to the oxidation electrolytic cell 2 and oxygen, where the oxygen comes from the oxygen-production electrolytic cell 3. The oxidation electrolytic cell 2 and the oxygen-production electrolytic cell 3 each are provided with an electrolytic cell separator to divide a corresponding electrolytic cell into an anode cell zone and a cathode cell zone. An electrolytic cell separator 6-1 of the oxidation electrolytic cell 2 is an anion exchange membrane. An electrolytic cell separator 6-2 of the oxygen-production electrolytic cell 3 is a filter cloth. Cathode cell zones of the oxidation electrolytic cell 2 and the oxygen-production electrolytic cell 3 each are provided with a liquid flow stirrer and a sensor.

In this example, the etching machine 1 and an anode cell zone of the oxidation electrolytic cell 2 are respectively connected to the mixing-exchange tank through a liquid flow circulation pipeline, such that an etching working solution circulates among the etching machine, the mixing-exchange tank, and the anode cell zone of the oxidation electrolytic cell 2, and an anode of the oxidation electrolytic cell 2 directly electrochemically oxidizes a cuprous ammonia complex in the etching working solution. In addition, oxygen produced by the oxygen-production electrolytic cell 3 and a small amount of oxygen produced by the oxidation electrolytic cell 2 are introduced directly into a solution in the mixing-exchange tank through the vacuum ejector 19, such that an etching working solution in the etching machine is rich in oxygen, and the etching can be accelerated through both the oxidation of metallic copper by the oxygen in the etching working solution and the direct electrochemical oxidation of a cuprous ammonia complex in the etching working solution by an anode of the oxidation electrolytic cell 2 to improve an etching production efficiency.

The etching machine 1 is a spray-type etching machine, and the spray-type etching machine is provided with sensors 28-1, 28-2, 28-3, and 28-4. The temporary storage tank 10-3 as a mixing-exchange tank is provided with a sensor 28-5, a sensor 28-6, a sensor 28-7, a sensor 28-8, and a sensor 28-9.

A temporary storage tank 10-5 is configured to receive a cathode electrolyte overflowing from the oxidation electrolytic cell 2 and the oxygen-production electrolytic cell 3 and prepare a regenerated etching sub-solution. The temporary storage tank 10-5 is provided with a sensor 28-12, a sensor 28-13, a sensor 28-14, and a sensor 28-15. The regenerated etching sub-solution from the temporary storage tank 10-5 is temporarily stored in a temporary storage tank 10-6, and the regenerated etching sub-solution is added to the mixing-exchange tank according to a set program.

The sensor 28-1 and the sensor 28-9 are thermometers, the sensor 28-2, the sensor 28-7, a sensor 28-11, and a sensor 28-13 are gravitometers, the sensor 28-3, the sensor 28-8, a sensor 28-10, and a sensor 28-12 are ORP meters, the sensor 28-4, the sensor 28-5, and the sensor 28-14 are pH meters, and the sensor 28-6 and the sensor 28-15 are liquid level meters. On-site data of all sensors are transmitted to the automatic program controller 29 for processing, such that the apparatus can automatically operate according to a set program.

An etching working solution is fed into the etching machine, the mixing-exchange tank, and an anode cell zone of the oxidation electrolytic cell 2, where a waste etching solution is fed from a temporary storage tank 10-2 to cathode cell zones of the oxidation electrolytic cell 2-1 and the oxygen-production electrolytic cell 3; a plurality of circuit boards 17 (etching-resist layers are shown in Table 3) are successively placed in the etching machine; and all other devices of the etching machine are started to allow etching and preparation of a regenerated etching sub-solution. A copper etching agent concentration in a solution in the mixing-exchange tank is set to be higher than a copper etching agent concentration in the etching working solution in the etching machine, that is, a value of the sensor 28-8 is greater than a value of the sensor 28-3. A rotational speed of a pump 16-7 and/or a gate valve opening of a valve 15-2 is/are controlled to control a flow rate for delivering the solution in the mixing-exchange tank to the etching machine, so as to maintain normal etching. When it is detected by the sensor 28-6 (a liquid level meter) of the mixing-exchange tank that the mixing-exchange tank is fully filled, a pump 16-6 is shut down and a pump 16-4 is started, such that a solution in the liquid flow buffer tank 22-1 is pumped into the temporary storage tank 10-2 for temporary storage. The ORP meter arranged on the mixing-exchange tank controls a size of a working current or a shutdown of the electrolytic power supply 7-1 and the electrolytic power supply 7-2 by detecting an ORP value of a solution.

### Example 10

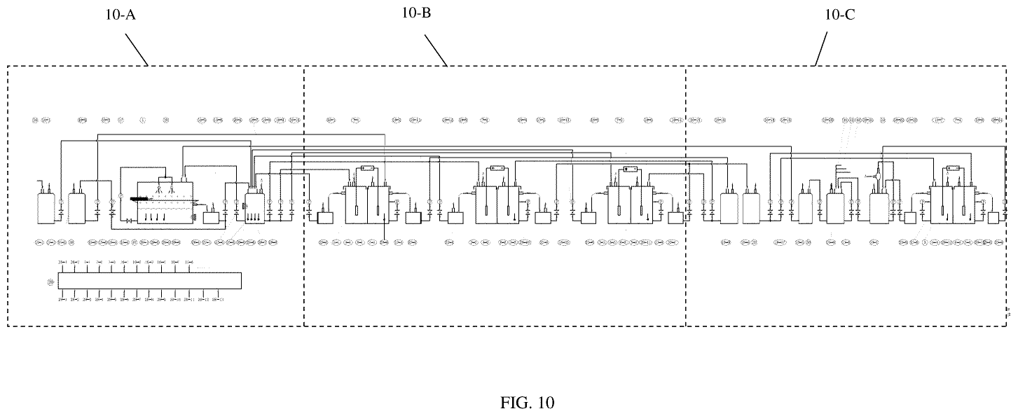

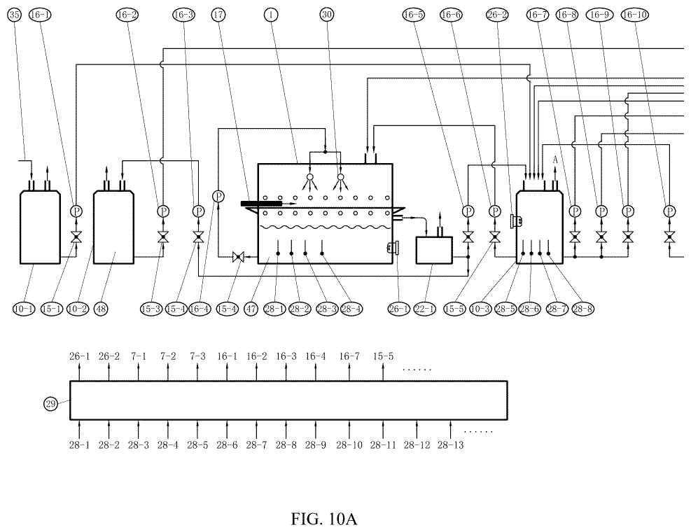

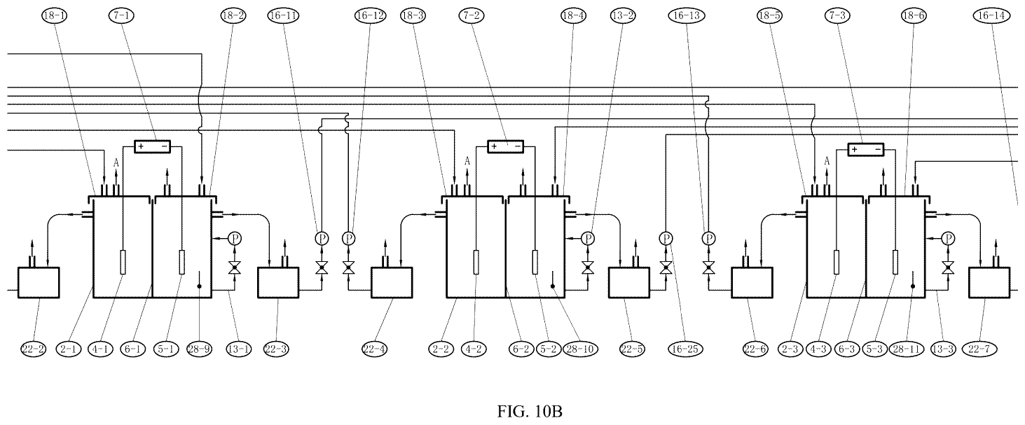

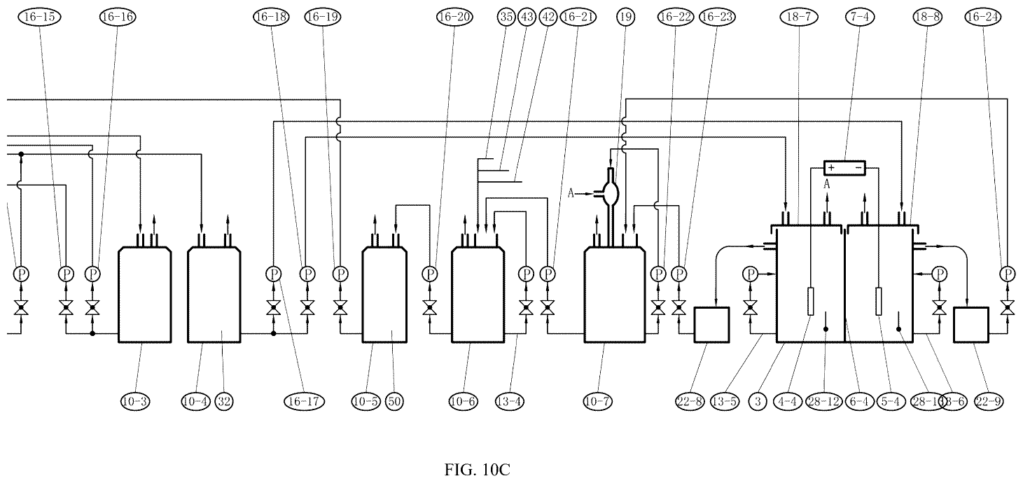

As shown in FIG. 10 and its enlarged views FIG. 10A, FIG. 10B and FIG. 10C, an apparatus for etching a circuit board with alkaline tetraamminecopper (II) sulfate is provided, including: an etching machine 1, seven temporary storage tanks 10, six liquid flow stirrers, nine liquid flow buffer tanks, three oxidation electrolytic cells 2, an oxygen-production electrolytic cell 3, four electrolytic power supplies 7, two heat exchangers, thirteen sensors, an automatic program controller 29, a valve, and a pump. A temporary storage tank 10-3 serves as a mixing-exchange tank.

In this example, copper is extracted through progressive electrolysis, where the oxidation electrolytic cell 2-1 serves as a grade-A metal electroextraction cell, the oxidation electrolytic cells 2-2 and 2-3 constitute a grade-B metal electroextraction cell, and the oxygen-production electrolytic cell 3 serves as a grade-C metal electroextraction cell. A cathode cell zone of the grade-A metal electroextraction cell is configured to reduce a copper etching agent concentration in a waste etching solution; and after the copper etching agent concentration meets a process requirement, a cathode electrolyte overflowing from the grade-A metal electroextraction cell is fed into a cathode cell zone of the grade-B metal electroextraction cell for copper electroextraction, and then a part of a cathode electrolyte overflowing from the grade-B metal electroextraction cell is fed into a cathode cell zone of the grade-C metal electroextraction cell for copper electroextraction. In addition, a part of the cathode electrolyte overflowing from the grade-B metal electroextraction cell is fed into an anode cell zone of the grade-C metal electroextraction cell for oxidation and oxygen production.

The above electrolytic cells each are provided with an electrolytic cell separator configured to divide a corresponding electrolytic cell into an anode cell zone and a cathode cell zone. The cathode cell zone is provided with a sensor and a liquid flow stirrer. An electrolytic cell separator 6-1 is a reverse osmosis membrane, an electrolytic cell separator 6-2 is a bipolar membrane, an electrolytic cell separator 6-3 is an anion exchange membrane, and an electrolytic cell separator 6-4 is a cation exchange membrane. An electrolytic anode for each electrolytic cell is an insoluble anode with a titanium-based coating, an electrolytic cathode 5-1 is conductive graphite, electrolytic cathodes 5-2 and 5-3 are copper plates, and an electrolytic cathode 5-4 is a stainless steel.

A regenerated etching sub-solution is prepared in a temporary storage tank 10-6.

In this example, a copper etching agent-oxidation regeneration reaction supply source refers to the oxidation electrolytic cells 2-1, 2-2, and 2-3.

In this example, the etching machine is connected to the mixing-exchange tank through a liquid flow circulation pipeline, and the mixing-exchange tank is connected to anode cell zones of the oxidation electrolytic cells 2-1, 2-2, and 2-3 through a liquid flow circulation pipeline, such that an etching working solution and electrolytes in the three anode cell zones are mixed in the mixing-exchange tank, and electrolytic anodes of the oxidation electrolytic cells directly electrochemically oxidize a cuprous ammonia complex in the etching working solution. Oxygen produced in anode cell zones of the three oxidation electrolytic cells 2-1, 2-2, and 2-3 and an anode cell zone of the oxygen-production electrolytic cell 3 is introduced into a temporary storage tank 10-7 through an ejector 19 to undergo a chemical oxidation reaction with a solution.

The etching machine 1 is a spray-type etching machine, and the spray-type etching machine is provided with sensors 28-1, 28-2, 28-3, and 28-4. The temporary storage tank 10-3 as a mixing-exchange tank is provided with a sensor 28-5, a sensor 28-6, a sensor 28-7, and a sensor 28-8.

The sensor 28-1 and the sensor 28-5 are pH meters, a sensor 28-2, a sensor 28-10, a sensor 28-11, and a sensor 28-13 are gravitometers, the sensor 28-3, the sensor 28-7, a sensor 28-9, and a sensor 28-12 are ORP meters, the sensor 28-4 and the sensor 28-8 are thermometers, and the sensor 28-6 is a liquid level meter. Data of all sensors are transmitted to the automatic program controller 29 for processing, such that the apparatus operates normally according to a set program.

An etching working solution is fed into the etching machine, the mixing-exchange tank, and anode cell zones of the three oxidation electrolytic cells, where a waste etching solution in a temporary storage tank 10-2 is fed into the cathode cell zone of the grade-A metal electroextraction cell, a cathode electrolyte overflowing from the grade-A metal electroextraction cell is fed into a cathode cell zone of the grade-B metal electroextraction cell, and a cathode electrolyte overflowing from the grade-B metal electroextraction cell after copper electroextraction is fed into anode and cathode cell zones of the grade-C metal electroextraction cell; a plurality of circuit boards 17 (etching-resist layers are shown in Table 3) are successively placed in the etching machine; and a pump 16-4 is started to make an etching working solution flow in a spray circulation manner, pumps 16-7, 16-8, and 16-9 are started to make a solution circulate between the mixing-exchange tank and the anode cell zones of the oxidation electrolytic cells, and electrolytic power supplies 7-1, 7-2, 7-3, and 7-4 are started to make the four electrolytic cells conduct electrolysis, respectively.

A copper etching agent concentration in a solution in the mixing-exchange tank is set to be higher than a copper etching agent concentration in an etching working solution in the etching machine. When a measurement result of the sensor 28-3 (an ORP meter) of the etching machine is lower than a process set value, a gate valve opening of a valve 15-5 is controlled to control a flow rate for pumping the solution in the mixing-exchange tank into the etching machine, so as to maintain normal etching. An overflow solution from the etching machine flows into a liquid flow buffer tank 22-1 and is pumped back to the mixing-exchange tank for circulation.

When a liquid level in the mixing-exchange tank reaches a set point, a pump 16-3 is started and a pump 16-5 is shut down, such that a solution in the liquid flow buffer tank 22-1 is pumped into the temporary storage tank 10-2 and temporarily stored as a waste etching solution.

During an etching process, the sensor 28-1 (a pH meter) in the etching machine detects whether an etching solution has a set value, and when an on-site measured value is lower than the set value, the automatic program controller 29 can control a pump 16-19 to feed a regenerated etching sub-solution 50 into the etching machine. When an on-site detected value of the sensor 28-5 (a pH meter) in the mixing-exchange tank is lower than a preset value, the automatic program controller 29 can control a metering pump 16-1 to feed ammonia water into the mixing-exchange tank for supplementation, such that an etching working solution allows stable etching production. The ORP meter arranged on the mixing-exchange tank transmits a detected ORP value of a solution to the automatic program controller 29 for processing to control a size of a working current or a shutdown of the electrolytic power supplies 7-1, 7-2, and 7-3.

### Examples 11 to 14

The apparatus shown in FIG. 10 is used to repeat the operations in Example 10 according to the parameters of etching working solutions and types of complexed ammonia supply sources in Tables 1 and 2. Parameters of a circuit board for an etching test in this example are shown in Table 3. A circuit board undergoing copper etching is checked, and etching rate and etching-resist layer results of the circuit board are recorded in Table 3.

### Comparative Example 1

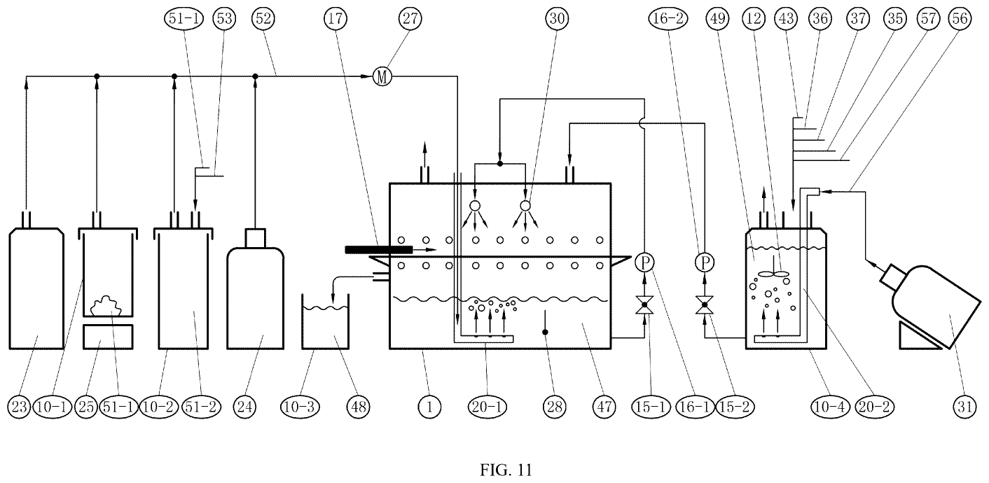

FIG. 11 is a schematic diagram of an apparatus in Comparative Example 1. This comparative example is different from FIG. 2 in that the oxidation electrolytic cell 2 is not provided.

In this comparative example, only oxygen is used as the copper etching agent-oxidation regeneration reaction supply source, and a source of the oxygen is consistent with the oxygen source in Example 2.

In this comparative example, the same alkaline tetraamminecopper (II) sulfate etching solution as in Example 2 is adopted, and parameters of a circuit board for an etching test are shown in Table 3. A circuit board undergoing copper etching is checked, and etching rate and etching-resist layer results of the circuit board are recorded in Table 3.

### Comparative Example 2

In this comparative example, the same alkaline tetraamminecopper (II) sulfate etching solution as in Example 2 and a conventional alkaline etching process are adopted for an etching test.

In this comparative example, the same alkaline tetraamminecopper (II) sulfate etching solution as in Example 2 is adopted, and parameters of a circuit board for an etching test are shown in Table 3. A circuit board undergoing copper etching is checked, and etching rate and etching-resist layer results of the circuit board are recorded in Table 3.

### Comparative Example 3

A [Cu(NH₃)₄]SO₄ solution as an etching solution and a conventional alkaline etching process are adopted for an etching test. An etching working solution has a copper ion concentration of 70 g/L.

Parameters of a circuit board for an etching test in this comparative example are shown in Table 3. A circuit board undergoing copper etching is checked, and etching rate and etching-resist layer results of the circuit board are recorded in Table 3.

### Comparative Examples 4 to 6

A conventional alkaline ammonium cupric chloride etching solution and a conventional alkaline etching process are adopted for an etching test. An etching working solution has a copper ion concentration of 140 g/L to 150 g/L and a pH of 8.8.

Parameters of a circuit board for an etching test in this comparative example are shown in Table 4. A circuit board undergoing copper etching is checked, and etching rate and etching-resist layer results of the circuit board are recorded in Table 4.

The present disclosure may be embodied in other specific forms without departing from the spirit or essential characteristics of the present disclosure. The above examples of the present disclosure can only be regarded as descriptions rather than limitations of the present disclosure. Therefore, any minor alterations, equivalent changes, and modifications of the above examples according to the technical spirit of the present disclosure shall be within the scope of the technical solutions of the present disclosure.

TABLE 1

| | Copper | | Ammonia and | Formic | Ammonium | | | | Etching |
|---|---|---|---|---|---|---|---|---|---|
| | ion | [SO₄²⁻] | ammonium | acid | formate | Hydroxylamine | | ORP | temperature |
| System | (g/L) | (mol/L) | (mol/L) | (mol/L) | (mol/L) | (mol/L) | pH | (mV) | (° C.) |
| Example | 55-65 | 2 | 7 | 0.5 | 2 | — | 8.1-8.8 | — | 50 |
| 1 | | | | | | | | | |
| Example | 10-32 | 4 | 18 | — | 0.0001 | — | 11-11.5 | — | 40 |
| 2 | | | | | | | | | |
| Example | 40-50 | 2.5 | 17 | 2 | — | 1 (hydroxylamine | 10.5-11 | −200~−100 | 40 |
| 3 | | | | | | sulfate) | | | |
| Example | 60-70 | 0.56 | 2 | — | 0.8 | 5 | 7-7.8 | 250~350 | 40 |
| 4 | | | | | | (hydroxylamine) | | | |
| Example | 70-80 | 0.33 | 8 | — | 6 | 0.5 | 7.6-8.5 | 100~200 | 30 |
| 5 | | | | | | (hydroxylamine | | | |
| | | | | | | sulfate) | | | |
| Example | 80-90 | 1.5 | 13 | 1 | — | 3 | 10-10.5 | −100~−50 | 45 |
| 6 | | | | | | (hydroxylamine) | | | |
| Example | 100-110 | 1.5 | 11 | — | 1.5 | 0.1 | 8.5-9 | 50~100 | 20 |
| 7 | | | | | | (hydroxylamine | | | |
| | | | | | | sulfate) | | | |
| Example | 110-120 | 2.5 | 15 | — | 0.5 | — | 9-9.6 | −50~0 | 50 |
| 8 | | | | | | | | | |
| Example | 130-140 | 1.8 | 10 | — | 0.1 | — | 9.6-10 | 0~50 | 50 |
| 9 | | | | | | | | | |
| Example | 70-80 | 1.2 | 12 | — | 0.3 | — | 10-10.5 | −20~20 | 10 |
| 10 | | | | | | | | | |
| Example | 120-130 | 3.8 | 15 | — | 4 | — | 8.4-8.9 | −50~0 | 55 |
| 11 | | | | | | | | | |
| Example | 45-55 | 3.5 | 16 | — | 0.05 | — | 9.5-10 | −200~−100 | 50 |
| 12 | | | | | | | | | |
| Example | 100-110 | 0.017 | 11 | — | 8 | — | 8-8.7 | 200~500 | 60 |
| 13 | | | | | | | | | |
| Example | 60-70 | 0.05 | 1.2 | — | 1 | — | 7-7.3 | 50~100 | 45 |
| 14 | | | | | | | | | |

TABLE 2

| | Complexed | | |
|---|---|---|---|
| | ammonia supply | | |
| | source for an | | |
| | etching working | Etching sub-solution/regenerated | Oxidation regeneration |
| System | solution | etching sub-solution | reaction supply source |
| Example | Ammonia water, | Mixed aqueous solution of ammonia | Oxidation electrolytic |
| 1 | ammonium sulfate, | water, ammonium sulfate, formic acid, | cell |
| | and ammonium | and ammonium formate | |
| | formate | | |
| Example | Ammonia, | Mixed aqueous solution of ammonia, | Oxidation electrolytic |
| 2 | ammonium sulfate, | ammonia water, ammonium carbonate, | cell + oxygen |
| | ammonium | ammonium bicarbonate, ammonium | (commercial oxygen, |
| | carbonate, | bisulfate, ammonium sulfate, and | oxygen produced by a |
| | ammonium | ammonium formate | molecular sieve |
| | bicarbonate, | | oxygen-production |
| | ammonia water, | | machine, and oxygen |
| | ammonium | | produced by a |
| | bisulfate, and | | chemical reaction) |
| | ammonium formate | | |
| Example | Ammonia water and | Mixed aqueous solution of ammonia | Oxidation electrolytic |
| 3 | ammonium sulfate | water, formic acid, ammonium sulfate, | cell + oxygen (oxygen |
| | | and hydroxylamine sulfate | produced by |
| | | | electrolysis) |
| Example | Ammonia water, | Solution produced after a reaction of a | Oxidation electrolytic |
| 4 | ammonium sulfate, | mixed solution of a solution produced | cell + oxygen (oxygen |
| | and ammonium | after copper electroextraction, | produced by |
| | formate | ammonia water, ammonium sulfate, | electrolysis) |
| | | ammonium formate, and | |
| | | hydroxylamine with oxygen and an | |
| | | ammonia gas discharged by an etching | |
| | | production line | |
| Example | Ammonia water, | Solution produced after a reaction of a | Oxidation electrolytic |
| 5 | ammonium sulfate, | mixed solution of a solution produced | cell |
| | and ammonium | after copper electroextraction, | |
| | formate | ammonia water, ammonium sulfate, | |
| | | ammonium formate, and | |
| | | hydroxylamine sulfate with oxygen | |
| | | and an ammonia gas escaping from an | |
| | | etching production line and an | |
| | | oxidation electrolytic cell | |
| Example | Ammonia water and | Solution produced after a reaction of a | Oxidation electrolytic |
| 6 | ammonium sulfate | mixed solution of a solution produced | cell |
| | | after copper electroextraction, | |
| | | ammonia water, ammonium sulfate, | |
| | | formic acid, and hydroxylamine with | |
| | | oxygen and an ammonia gas escaping | |
| | | from an etching production line and an | |
| | | oxidation electrolytic cell | |
| Example | Ammonia water, | Mixed solution of a solution produced | Two oxidation |
| 7 | ammonium sulfate, | after oxidation in an anode cell zone of | electrolytic cells |
| | and ammonium | a grade-B metal electroextraction cell, | |
| | formate | ammonium sulfate, ammonia water, | |
| | | ammonium formate, and | |
| | | hydroxylamine sulfate | |
| Example | Ammonia water, | Mixed aqueous solution of ammonium | Two oxidation |
| 8 | ammonium sulfate, | sulfate, ammonia water, and | electrolytic cells + |
| | and ammonium | ammonium formate | oxygen (oxygen- |
| | formate | | production electrolytic |
| | | | cell) |
| Example | Ammonia water, | Solution produced after a reaction of a | Oxidation electrolytic |
| 9 | ammonium sulfate, | mixed solution of a solution produced | cell + oxygen |
| | and ammonium | after copper electroextraction, | (oxygen-production |
| | formate | ammonia water, ammonium sulfate, | electrolytic cell) |
| | | and ammonium formate with oxygen | |
| | | and an ammonia gas escaping from an | |
| | | etching production line and an | |
| | | oxidation electrolytic cell | |
| Examples | Ammonia water, | Mixed solution of a solution produced | Three oxidation |
| 10 to 14 | ammonium sulfate, | after a reaction of a solution produced | electrolytic cells |
| | and ammonium | after oxidation in an anode cell zone of | |
| | formate | a grade-C metal electroextraction cell | |
| | | with oxygen and an ammonia gas | |
| | | escaping from an electrolytic cell, | |
| | | ammonium sulfate, ammonia water, | |
| | | and ammonium formate | |

TABLE 3

| | Etching | Circuit | Etching-resist layer | | |
|---|---|---|---|---|---|
| | rate | copper | | Thick- | |
| | (μm/ | thickness | | ness | Corrosiveness |
| System | min) | (μm) | Material | (μm) | after etching |
| Example 1 | 30 | 35 | Tin | 8 | No corrosion |
| Example 2 | 15 | 35 | Tin | 8 | No corrosion |
| Example 3 | 18 | 35 | Tin | 3 | No corrosion |
| Example 4 | 20 | 70 | Silver | 6 | No corrosion |
| Example 5 | 17 | 35 | Silver | 2 | No corrosion |
| Example 6 | 32 | 70 | Immersion | 1 | No corrosion |
| | | | tin | | |
| Example 7 | 26 | 70 | Silver | 7 | No corrosion |
| Example 8 | 44 | 70 | Tin | 6 | No corrosion |
| Example 9 | 15 | 35 | Immersion | 0.8 | No corrosion |
| | | | tin | | |
| Example 10 | 24 | 70 | Silver | 10 | No corrosion |
| Example 11 | 20 | 70 | Immersion | 1 | No corrosion |
| | | | tin | | |
| Example 12 | 15 | 70 | Immersion | 1 | No corrosion |
| | | | tin | | |
| Example 13 | 41 | 70 | Immersion | 1 | No corrosion |
| | | | tin | | |
| Example 14 | 20 | 35 | Silver | 3 | No corrosion |
| Comparative | 6 | 35 | Tin | 8 | No corrosion |
| Example 1 | | | | | |
| Comparative | 4.5 | 35 | Tin | 3 | No corrosion |
| Example 2 | | | | | |
| Comparative | 7 | 35 | Tin | 3 | No corrosion |
| Example 3 | | | | | |

TABLE 4

| | Circuit | | | | |
|---|---|---|---|---|---|
| | copper | Etching-resist layer | | | |
| | thickness | | Thickness | Corrosiveness after | |
| System | (μm) | Material | (μm) | etching | Film residue |
| Example 1 | 35 | Tin | 8 | No corrosion | There is a little film |
| | | | | | entrapment after film |
| | | | | | removal, and there is |
| | | | | | no film residue after |
| | | | | | etching |
| Example 3 | 35 | Tin | 3 | No corrosion | There is no film |
| | | | | | entrapment and |
| | | | | | residue after film |
| | | | | | removal |
| Comparative | 35 | Tin | 3 | There is significant | There is no film |
| Example 4 | | | | corrosion, and small holes | entrapment and |
| | | | | are formed in an etching- | residue after film |
| | | | | resist layer to expose a | removal |
| | | | | copper circuit | |
| Comparative | 35 | Silver | 3 | There is significant | There is no film |
| Example 5 | | | | corrosion, and a part of an | entrapment and |
| | | | | etching-resist layer | residue after film |
| | | | | disappears to expose a | removal |
| | | | | copper circuit | |
| Comparative | 35 | Tin | 8 | There is significant | There is a little film |
| Example 6 | | | | corrosion, but an etching- | entrapment after film |
| | | | | resist layer is not | removal, and there is |
| | | | | completely perforated to | still a film residue |
| | | | | expose a copper circuit | after etching |

What is claimed is:

1. A process for etching a circuit board with alkaline tetraamminecopper (II) sulfate, comprising an etching solution for etching the circuit board coated with an etching-resist metal layer, wherein the etching solution comprises tetraamminecopper (II) sulfate, a complexed ammonia supply source, and a formate supply source; and the tetraamminecopper (II) sulfate serves as a copper etching agent to etch the circuit board, and the copper etching agent in the etching solution is regenerated by a copper etching agent-oxidation regeneration reaction supply source to maintain an etching rate.

2. The process for etching a circuit board with alkaline tetraamminecopper (II) sulfate according to claim 1, wherein in the etching solution, a pH is 7 to 11.5, a concentration of copper ions is 10 g/L to 140 g/L, a molar concentration of sulfate ions is at least 0.01 time a molar concentration of copper ions and does not exceed 4 mol/L, a total molar concentration of ammonia and ammonium ions is at least 1 time the molar concentration of copper ions and does not exceed 18 mol/L, and a concentration of formate ions is 0.0001 mol/L to 8 mol/L.

3. The process for etching a circuit board with alkaline tetraamminecopper (II) sulfate according to claim 2, wherein the complexed ammonia supply source is a chemical capable of providing ammonia and/or ammonium ions, and comprises one or more selected from the group consisting of ammonia water, ammonia, ammonium carbonate, ammonium bicarbonate, ammonium sulfate, ammonium bisulfate, and ammonium formate; and the formate supply source is formic acid and/or ammonium formate.

4. The process for etching a circuit board with alkaline tetraamminecopper (II) sulfate according to claim 2, wherein the copper etching agent-oxidation regeneration reaction supply source is an oxidation electrolytic cell configured to allow an oxidation regeneration reaction for an etching working solution;
the oxidation electrolytic cell is provided with an electrolytic cell separator configured to divide the oxidation electrolytic cell into an anode cell zone and a cathode cell zone, wherein the electrolytic cell separator is configured to effectively prevent cations in the anode cell zone from entering the cathode cell zone; and the anode cell zone is connected through a pipeline to an etching machine that is filled with an etching working solution and is conducting etching, such that the etching working solution is able to circulate between the anode cell zone and the etching machine to maintain a concentration of a copper etching agent in the etching working solution.

5. The process for etching a circuit board with alkaline tetraamminecopper (II) sulfate according to claim 4, wherein during a continuous etching production process, in order to maintain a stable component ratio of the etching working solution, an etching sub-solution comprising sulfate and complexed ammonia supply sources is supplemented to the etching working solution; and
the etching sub-solution is added to any one or more selected from the group consisting of the following: the etching working solution in the etching machine, an anode electrolyte in the oxidation electrolytic cell, and a mixed solution of the etching working solution and the anode electrolyte.

6. The process for etching a circuit board with alkaline tetraamminecopper (II) sulfate according to claim 5, wherein the etching solution further comprises hydroxylamine at a concentration of no more than 5 mol/L to promote a regeneration reaction for the etching solution.

7. The process for etching a circuit board with alkaline tetraamminecopper (II) sulfate according to claim 2, wherein the copper etching agent-oxidation regeneration reaction supply source further comprises oxygen; specifically, the oxygen is introduced into the etching working solution and/or the anode electrolyte in the oxidation electrolytic cell to assist in a chemical oxidation reaction to regenerate a cuprous ammonia complex in the etching working solution into the copper etching agent; and oxygen sources comprise: (1) commercial oxygen, (2) oxygen prepared by a molecular sieve oxygen-production machine, (3) oxygen prepared by a chemical reaction of an oxidant, and (4) oxygen prepared by an electrolysis method, wherein the oxygen prepared by the electrolysis method refers to oxygen escaping during an operation process of the oxidation electrolytic cell and/or oxygen produced by an additional oxygen-production electrolytic cell.

8. The process for etching a circuit board with alkaline tetraamminecopper (II) sulfate according to claim 7, wherein a waste alkaline tetraamminecopper (II) sulfate etching solution is subjected to copper and/or silver extraction through electroextraction with a metal electroextraction cell; and after the copper extraction through the electroextraction with the metal electroextraction cell, the waste alkaline tetraamminecopper (II) sulfate etching solution directly becomes a regenerated etching sub-solution or is used as one of raw materials to prepare a regenerated etching sub-solution, and the regenerated etching sub-solution is used as a part or all of the etching sub-solution;
when the metal electroextraction cell is not provided with an electroextraction cell separator, an electrolyte comprises a waste etching solution and/or a waste etching solution undergoing electrolysis; and
when the metal electroextraction cell is provided with an electroextraction cell separator configured to divide the metal electroextraction cell into an anode cell zone and a cathode cell zone, a cathode electrolyte comprises a waste etching solution and/or a waste etching solution undergoing electrolysis, an anode electrolyte is one or a mixed solution of two or more selected from the group consisting of an etching working solution, a waste etching solution, a cathode electrolyte undergoing electrolysis from the metal electroextraction cell, and a cathode electrolyte undergoing electrolysis from another metal electroextraction cell, and the electroextraction cell separator is one or more selected from the group consisting of a cation exchange membrane, an anion exchange membrane, a bipolar membrane, a reverse osmosis membrane, a neutral filter membrane, and a filter cloth.

9. A apparatus suitable for the process for etching a circuit board with alkaline tetraamminecopper (II) sulfate according to claim 1, comprising: an etching machine with an alkaline tetraamminecopper (II) sulfate etching solution as an etching working solution, and a copper etching agent-oxidation regeneration reaction supply device, wherein the copper etching agent-oxidation regeneration reaction supply device is an oxidation electrolytic cell, and the oxidation electrolytic cell is connected to the etching machine through at least two pipelines, such that the etching working solution is able to circulate between the oxidation electrolytic cell and the etching machine, the etching working solution directly undergoes an electrochemical oxidation reaction with an electrolytic anode when entering the oxidation electrolytic cell, and a cuprous ammonia complex in the etching working solution is regenerated into alkaline tetraamminecopper (II) sulfate Cu(NH₃)₄SO₄ as a copper etching agent;
the oxidation electrolytic cell is provided with an electrolytic cell separator configured to divide the oxidation electrolytic cell into an anode cell zone and a cathode cell zone; the anode cell zone is connected to the etching machine through a pipeline, such that the etching working solution is able to circulate between the anode cell zone and the etching machine to maintain a copper etching agent concentration in the etching working solution; and the electrolytic cell separator of the oxidation electrolytic cell is configured to effectively prevent cations in the anode cell zone from entering the cathode cell zone, and is specifically one or more selected from the group consisting of an anion exchange membrane, a bipolar membrane, and a reverse osmosis membrane.

10. The apparatus suitable for the process for etching a circuit board with alkaline tetraamminecopper (II) sulfate according to claim 9, wherein the copper etching agent-oxidation regeneration reaction supply device further comprises an oxygen supply unit, and the oxygen supply unit is connected to a unit filled with an etching working solution through a pipeline or communicates with the etching working solution through a pipeline, such that alkaline tetraamminecopper (II) sulfate Cu(NH₃)₄SO₄ as a copper etching agent in the etching working solution is able to be regenerated through an oxygen oxidation reaction during an etching process of the etching working solution.

11. The apparatus suitable for the process for etching a circuit board with alkaline tetraamminecopper (II) sulfate according to claim 10, wherein a mixing-exchange tank is further provided at a connecting pipeline between the etching machine and the anode cell zone of the oxidation electrolytic cell, such that the etching working solution and an anode electrolyte in the oxidation electrolytic cell are mixed and exchanged in the mixing-exchange tank through respective liquid flow circulation pipelines.

12. The apparatus suitable for the process for etching a circuit board with alkaline tetraamminecopper (II) sulfate according to claim 11, wherein a metal electroextraction cell is further provided to receive a waste alkaline tetraamminecopper (II) sulfate etching solution from the etching machine and extract copper and/or silver from the waste alkaline tetraamminecopper (II) sulfate etching solution through electroextraction.
